(19) United States
(12) Patent Application Publication
(10) Pub. No.: US 2013/0107138 A1
(43) Pub. Date: May 2, 2013

(54) TELEVISION RECEIVER AND ELECTRONIC APPARATUS

(71) Applicants: Takuo Matsumoto, Tokyo (JP); Tetsuo Okazaki, Tokyo (JP)

(72) Inventors: Takuo Matsumoto, Tokyo (JP); Tetsuo Okazaki, Tokyo (JP)

(73) Assignee: KABUSHIKI KAISHA TOSHIBA, Tokyo (JP)

(21) Appl. No.: 13/592,666

(22) Filed: Aug. 23, 2012

(30) Foreign Application Priority Data
Oct. 28, 2011 (JP) 2011-238019

(51) Int. Cl. H05K 7/02; H04N 5/64

(52) U.S. Cl. 348/836; 361/810; 348/E05.096; 348/E05.128

(57) ABSTRACT

According to one embodiment, an electronic apparatus includes: a first housing portion configured to cover a part of an electronic component; a second housing portion configured to cover another part of the electronic component that is different from the part covered by the first housing portion; a first coupling portion at one end of the first housing portion; a second coupling portion at one end of the second housing portion, outside the first coupling portion, and coupled to the first coupling portion; a third coupling portion at the other end of the first housing portion; a fourth coupling portion at the other end, with respect to the second coupling portion, of the second housing portion, inside the third coupling portion, and coupled to the third coupling portion; and a function component attached to the second housing portion, the function component covering the third coupling portion.

### CROSS-REFERENCE TO RELATED APPLICATIONS

This application is based upon and claims the benefit of priority from Japanese Patent Application No. 2011-238019, filed Oct. 28, 2011, the entire contents of which are incorporated herein by reference.

### FIELD

Embodiments described herein relate generally to a television receiver and an electronic device.

### BACKGROUND

Conventionally known is an electronic apparatus that is configured such that no fastening member is exposed to the outer side of a housing.

In an electronic apparatus and a television receiver of this type, a configuration having fewer disadvantages or more advantages, such as a configuration requiring the reduced number of parts, has been desired.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view illustrating an example of a television receiver according to a first embodiment;

FIG. 2 is an exemplary side view illustrating the example of the television receiver in the embodiment;

FIG. 3 is an exemplary cross-sectional view cut along a line III-III of FIG. 1 in the embodiment;

FIG. 4 is an exemplary cross-sectional view cut along a line IV-IV of FIG. 1 in the embodiment;

FIG. 5 is an exemplary perspective view illustrating an example of an electronic apparatus according to a second embodiment;

FIG. 6 is an exemplary front view illustrating the example of the electronic apparatus in the embodiment;

FIG. 7 is an exemplary rear view illustrating the example of the electronic apparatus in the embodiment;

FIG. 8 is an exemplary side view illustrating the example of the electronic apparatus in the embodiment;

FIG. 9 is an exemplary side view illustrating the example of the electronic apparatus in the embodiment when seen from a different direction from FIG. 8;

FIG. 10 is an exemplary side view illustrating the example of the electronic apparatus in the embodiment when seen from a different direction from FIGS. 8 and 9;

FIG. 11 is an exemplary side view illustrating the example of the electronic apparatus in the embodiment when seen from a different direction from FIGS. 8 to 10;

FIG. 12 is an exemplary exploded perspective view illustrating the example of the electronic apparatus in the embodiment;

FIG. 13 is an exemplary plan view illustrating an example of an inner configuration of the electronic apparatus in the embodiment;

FIG. 14 is an exemplary cross-sectional view cut along a line XIV-XIV of FIG. 6 in the embodiment;

FIG. 15 is an exemplary perspective view illustrating an example of a state where the electronic apparatus in the embodiment is held on a docking station;

FIG. 16 is an exemplary side view illustrating the example of the state where the electronic apparatus in the embodiment is held on the docking station;

FIG. 17 is an exemplary perspective view illustrating an example of a first member of the electronic apparatus in the embodiment;

FIG. 18 is an exemplary perspective view illustrating an example of a second member of the electronic apparatus in the embodiment;

FIG. 19 is an exemplary perspective view illustrating an example of a third member of the electronic apparatus in the embodiment;

FIG. 20 is an exemplary perspective view illustrating an example of a housing of the electronic apparatus in the embodiment from which a battery is detached;

FIG. 21 is an exemplary perspective view illustrating the example of the housing of the electronic apparatus in the embodiment from which the battery is detached when seen from a different angle;

FIG. 22 is an exemplary perspective view illustrating the example of the housing of the electronic apparatus in the embodiment from which the battery is detached;

FIG. 23 is an exemplary perspective view illustrating the example of the housing of the electronic apparatus in the embodiment from which the battery is detached when seen from a different angle;

FIG. 24 is an exemplary perspective view illustrating the example of the housing of the electronic apparatus in the embodiment from which the battery is detached;

FIG. 25 is an exemplary perspective view illustrating the example of the housing of the electronic apparatus in the embodiment from which the battery is detached when seen from a different angle;

FIG. 26 is an exemplary cross-sectional view cut along a line XXVI-XXVI of FIG. 24 in the embodiment;

FIG. 27 is an exemplary perspective view illustrating an example of a part of the first member of the electronic apparatus in the embodiment;

FIG. 28 is an exemplary perspective view illustrating an example of a part of the second member of the electronic apparatus in the embodiment;

FIG. 29 is an exemplary cross-sectional view cut along a line XXIX-XXIX of FIG. 6 in the embodiment;

FIG. 30 is an exemplary perspective view illustrating an example of the second member and the third member of the electronic apparatus in the embodiment;

FIG. 31 is an exemplary perspective view illustrating an example of an electronic apparatus according to a first variation of the embodiment;

FIG. 32 is an exemplary exploded cross-sectional view (partial side view) illustrating an example of an electronic apparatus according to a second variation of the embodiment;

FIG. 33 is an exemplary cross-sectional view (partial side view) illustrating the example of the electronic apparatus in the variation of the embodiment;

FIG. 34 is an exemplary exploded cross-sectional view (partial side view) illustrating an example of an electronic apparatus according to a third variation of the embodiment;

FIG. 35 is an exemplary cross-sectional view (partial side view) illustrating the example of the electronic apparatus in the variation of the embodiment; and

FIG. 36 is an exemplary cross-sectional view (partial side view) illustrating an example of an electronic apparatus according to a fourth variation of the embodiment.

### DETAILED DESCRIPTION

In general, according to one embodiment, a television receiver comprises: a display comprising a screen and an edge at an area other than the screen; a first housing portion covering at least a part of the edge of the display; a second housing portion at a side opposite the display; a third housing portion at a side opposite the screen, between the second housing portion and the screen; a first coupling portion at one end of the first housing portion; a second coupling portion at one end of at least one of the second housing portion and the third housing portion, outside the first coupling portion, and coupled to the first coupling portion; a third coupling portion at the other end of the first housing portion; a fourth coupling portion at the other end, with respect to the second coupling portion, of at least one of the second housing portion and the third housing portion, inside the third coupling portion, and coupled to the third coupling portion; a coupling member configured to couple the third coupling portion and the fourth coupling portion, at least a part of the coupling member outside the third coupling portion; and a module attached to at least one of the second housing portion and the third housing portion, the module covering the coupling member from outside at least one of the second housing portion and the third housing portion.

The same elements are comprised in exemplary embodiments described below. Therefore, in explanations below, the same reference numerals are assigned to the same elements, and redundant explanations thereof are omitted. In addition, in each of the drawings, directions (an X direction, a Y direction, and a Z direction) are illustrated for convenience. The X direction corresponds to the longitudinal direction of a display screen of a television receiver in a front view. The Y direction corresponds to the short side direction of the display screen viewed from the front. The Z direction corresponds to the front-back direction of the display screen (depth direction, the thickness direction of a housing) viewed from the front. The X direction, the Y direction, and the Z direction perpendicularly cross each other.

Furthermore, in the following embodiment, a case where an electronic apparatus is configured as a television receiver, or a tablet-type or slate-type personal computer is described. However, an electronic apparatus according to the embodiment is not limited thereto. The electronic apparatus according to the embodiment can be configured as various electronic apparatuses such as a notebook or desktop personal computer, a smart phone, a smart television, a smart book, a mobile phone, a personal digital assistant (PDA), a video display device, and a video phone.

### First Embodiment

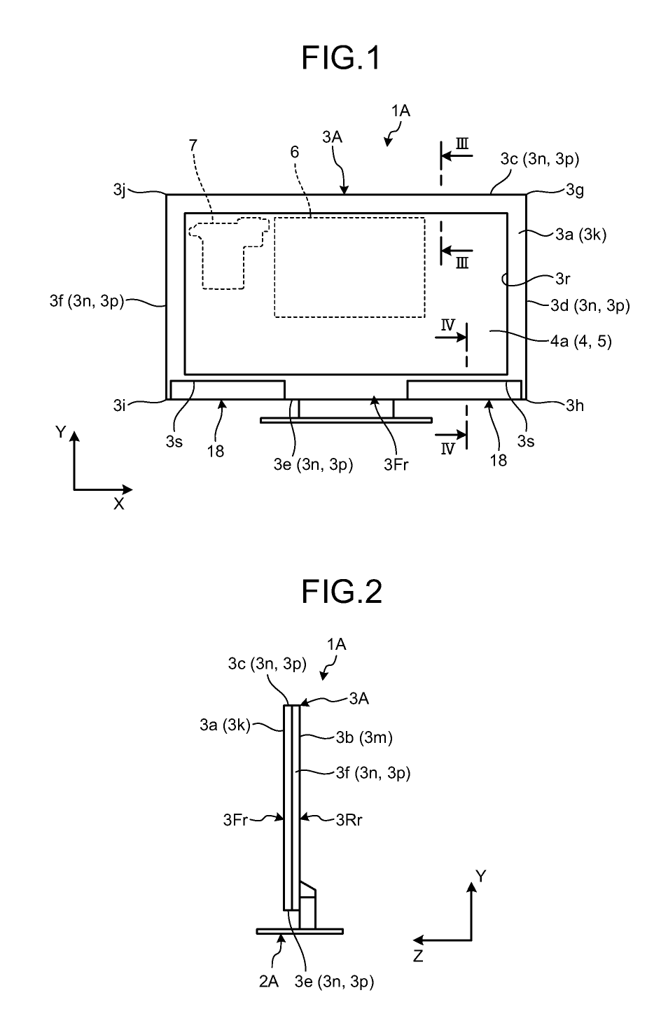

A television receiver 1A as an example of an electronic apparatus according to the first embodiment comprises a supporting portion 2A (stand portion, table, stand) and a housing 3A as illustrated in FIGS. 1 and 2. The supporting portion 2A is placed on a placement portion (placement surface, not illustrated) such as a desk, a shelf, and a table and supports the housing 3A. The supporting portion 2A may support the housing 3A in a secured manner or in a movable manner (rotationally movable manner, slidable manner). The rotational movement mode of the housing 3A with respect to the supporting portion 2A is of tilt, swivel, and pivot, for example.

The housing 3A is configured to have a rectangular shape (in the first embodiment, a square shape as an example) when seen from the front side as illustrated in FIG. 1. Furthermore, the housing 3A is configured to have a flattened box shape that is thin in the front-rear direction as illustrated in FIG. 2. The housing 3A comprises a front surface 3a (front face, surface, first surface, first surface portion) and a back surface 3b (rear face, surface, second surface, second surface portion) at a side opposite to the front surface 3a. The front surface 3a and the back surface 3b are substantially parallel with each other. The housing 3A comprises four ends 3c to 3f (sides, edges) and four corners 3g to 3j (sharp portions, bent portions, ends) when seen from the front side, as illustrated in FIG. 1. The ends 3c and 3e are examples of long sides. The ends 3d and 3f are examples of short sides.

Furthermore, the housing 3A comprises a wall portion 3k (first portion, plate, frame, front wall portion, surface wall portion, ceiling wall portion) having the front surface 3a and a wall portion 3m (second portion, plate, back wall portion, rear wall portion, bottom wall portion) having the back surface 3b. The wall portions 3k and 3m have rectangular shapes (in the first embodiment, square shapes as an example). Furthermore, the housing 3A comprises four wall portions 3n (third portions, plates, side wall portions, end wall portions, erected wall portions, connecting portions). The wall portions 3n have side surfaces 3p (surfaces, circumferential surfaces, third surfaces) connecting between the wall portion 3k and the wall portion 3m. Furthermore, an opening 3r having a rectangular shape is provided on the wall portion 3k, as an example.

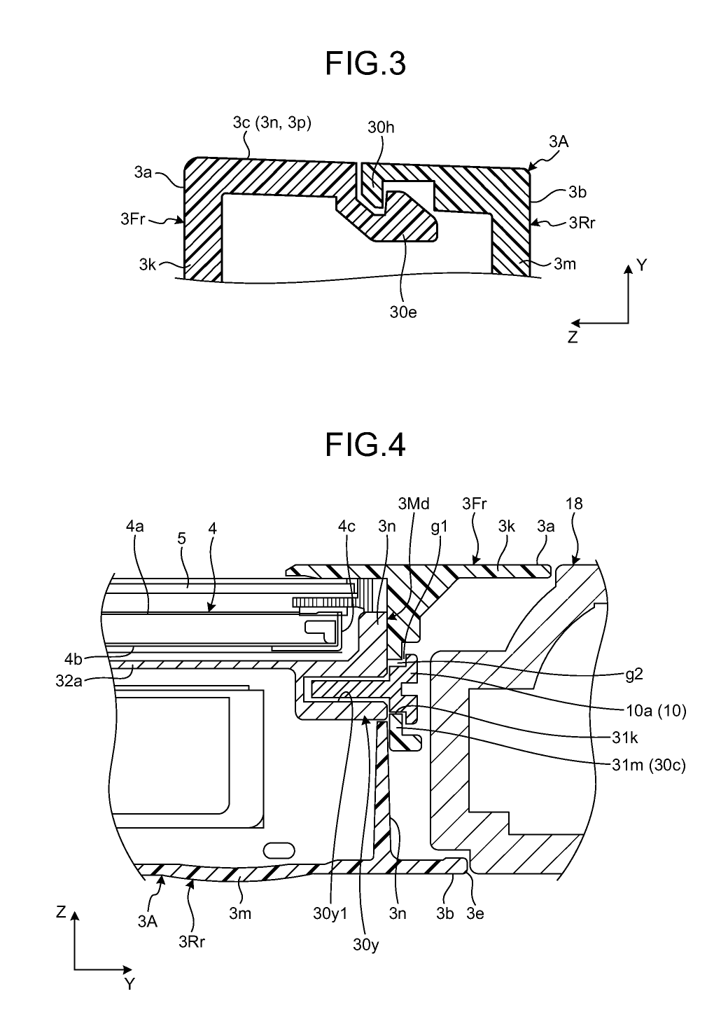

Furthermore, the housing 3A can be configured by combining a plurality of parts (divided members, members). The housing 3A comprises a first member 3Fr (first housing portion, first portion, front-side member, cover), and a second member 3Rr (second housing portion, second portion, back-side member, base, bottom), as an example. The first member 3Fr comprises at least the wall portion 3k. The second member 3Rr comprises at least the wall portion 3m. The wall portions 3n can be comprised in at least one of the first member 3Fr and the second member 3Rr (for example, second member 3Rr). Furthermore, the housing 3A comprises, in addition to the first member 3Fr and the second member 3Rr, a third member 3Md (third housing portion, third portion, intermediate member, separation member, barrier wall member, wall member, interposing member, inner plate, middle plate, middle frame, see FIGS. 3 and 4) that is located between the first member 3Fr and the second member 3Rr. In this case, the wall portions 3n can be also comprised in the third member 3Md. The housing 3A can be formed with a metal material, a synthetic resin material, or the like.

A display device 4 (display module, display, panel) is accommodated in the housing 3A. A display screen 4a of the display device 4 that is located at the side of the front surface 3a is exposed to a front side (outer side) of the housing 3A through the opening 3r. Therefore, a user can visually recognize the display screen 4a through the opening 3r from the front side. Furthermore, the display device 4 is configured to have a rectangular shape (in the first embodiment, a square shape as an example) when seen from the front side. Furthermore, the display device 4 is configured to have a flattened box shape that is thin in the front-rear direction. For example, the display device 4 is a liquid crystal display (LCD) or an organic electro-luminescent display (GELD).

An input operation panel 5 (touch panel, touch sensor, operation surface as an example) is provided at the front side (surface side, wall portion 3k side) of the display device 4. The input operation panel 5 is configured to be transparent and have a relatively thin rectangular shape and covers the display screen 4a. An operator (user or the like) performs an operation on the input operation panel 5 with his (her) hand or finger, or a stylus, for example, so as to execute an input processing. The operation performed by the operator includes touching, pressing, sliding the input operation panel 5, or moving his (her) hand or finger, or the stylus in the vicinity of the input operation panel 5. In addition, light emitted from the display screen 4a of the display device 4 passes through the input operation panel 5 so as to travel to the front side (outer side) of the housing 3A from the opening 3r of the wall portion 3k. The input operation panel 5 is an example of an input module.

A plurality of substrates (circuit substrates) 6 and 7 are accommodated in the housing 3A at the back side (rear side, behind, wall portion 3m side, side opposite to the display screen 4a) of the display device 4. The substrates 6 and 7 are arranged at positions that are different from each other and any of them are provided in parallel with the display device 4. In addition, the substrates 6 and 7 are provided in a state where they are separated from the wall portions 3k and 3m, and 3n, and the like, that is to say, in a state where a space (gap) is formed between each of the substrates 6 and 7 and each of the wall portions 3k and 3m, and 3n, and the like. The substrates 6 and 7 are preferably arranged to be aligned along the display device 4 so as not to overlap with each other in the thickness direction of the housing 3A. In addition, the substrates 6 and 7 are secured to the housing 3A (second member 3Rr or third member 3Md) with coupling members such as screws, for example.

A plurality of electronic parts (parts, elements, not illustrated) such as a central processing unit (CPU) are mounted on the substrates 6 and 7 (first substrate, first circuit substrate, control substrate, main substrate) illustrated in FIG. 1. The electronic parts include a heat generator. Furthermore, a cooling mechanism (heat dissipater, heat receiver, not illustrated) can be provided for an electronic part (heat generator) whose heat generation amount is large. At least a part of a control circuit (not illustrated) is constituted by the substrates 6 and 7 and the electronic parts. The control circuit can comprise a video signal processing circuit, a tuner module, a high-definition multimedia interface (HDMI) signal processor, an audio video (AV) input terminal, a remote controller signal receiver, a controller, a selector, an on-screen display interface, a storage module (for example, read only memory (ROM), random access memory (RAM), hard disk drive (HDD)), and a voice signal processing circuit, for example. The control circuit controls output of a video image (moving image, still image, or the like) on the display screen 4a of the display device 4, output of sound with a speaker (not illustrated), light emission from a light emitting diode (LED) (not illustrated), and the like. The display device 4, the speaker, the LED, and the like are examples of an output module.

Furthermore, in the first embodiment, battery accommodation portions 3s that accommodate batteries 18 (modules, parts, electronic parts, detachable parts, exchangeable parts) in a detachable manner are provided on the end 3e of the housing 3A, as an example, as illustrated in FIG. 1. To be more specific, the battery accommodation portions 3s are located on the end 3e of the housing 3A at two positions so as to be closer to corners 3h, 3i at both sides of the supporting portion 2A. The battery accommodation portions 3s are configured as rectangular recesses (openings) in a manner that the end 3e is recessed (cut out) toward the end c at the opposite side. The batteries 18 are attached so as to cover (close, fill) the recesses (openings). The batteries 18 extend along the end 3e. In the first embodiment, source power of the television receiver 1A can be obtained by the batteries 18 when an AC source cannot be used, and so on, as an example.

Furthermore, in the first embodiment, on the end 3c at the side opposite to the end 3e on which the battery accommodation portions 3s are provided, coupling portions 30e and 30h (engagement portions, claw portions, hook portions, hooking portions) are located at inner positions of the housing 3A with respect to the wall portion 3n of the housing 3A, as an example, as illustrated in FIG. 3. The first member 3Fr and at least one (in the example, the second member 3Rr as an example) of the second member 3Rr and the third member 3Md are coupled to each other on the coupling portions 30e and 30h. That is to say, the coupling portions 30e and 30h are covered by at least one of the first member 3Fr and the third member 3Md. Therefore, according to the first embodiment, the coupling portions 30e and 30h can be suppressed from being exposed, as an example. This makes it possible to suppress disadvantages due to exposure of the coupling portions 30e and 30h to the outside of the housing 3A from occurring. As the disadvantages, coupling is easily released and appearance is easily spoiled, for example.

Furthermore, in the first embodiment, the coupling portion 30h of at least one (in the first embodiment, the second member 3Rr as an example) of the second member 3Rr and the third member 3Md is located at an outer position of the housing 3A with respect to the coupling portion 30e of the first member 3Fr, as an example. Therefore, in the first embodiment, the first member 3Fr is suppressed from moving from the end 3e side to the end 3c side (from the lower side to the upper side in FIG. 3) with respect to at least one (in the first embodiment, the second member 3Rr as an example) of the second member 3Rr and the third member 3Md with engagement (coupling) of the coupling portions 30h, 30h, as an example. Furthermore, in the first embodiment, the first member 3Fr, and the second member 3Rr and the third member 3Md are suppressed from being separated from each other in the thickness direction of the housing 3A with the engagement (coupling) of the coupling portions 30e and 30h. It is to be noted that in the first embodiment, the first member 3Fr is not suppressed from moving from the end 3c side to the end 3e side (from the upper side to the lower side in FIG. 3) with respect to at least one (in the first embodiment, the second member 3Rr as an example) of the second member 3Rr and the third member 3Md with the engagement (coupling) of the coupling portions 30e and 30h. The coupling portion 30e is an example of a first coupling portion, and the coupling portion 30h is an example of a second coupling portion.

Furthermore, in the first embodiment, on the end 3e on which the battery accommodation portions 3s are provided, coupling portions 30c and 30y (engagement portions, claw portions, hook portions, hooking portions) are located at outer positions of the housing 3A with respect to the wall portion 3n of the housing 3A, as an example, as illustrated in FIG. 4. The first member 3Fr and at least one (in the first embodiment, the third member 3Md as an example) of the second member 3Rr and the third member 3Md are coupled to each other on the coupling portions 30c and 30y. In addition, the coupling portions 30c and 30y are coupled to each other with a screw 10 as an example of a coupling member. The coupling portion 30c comprises a protrusion 31m on which an opening 31k (through-hole, cutout, or the like, in the first embodiment, a through-hole as an example) is provided. The protrusion 31m protrudes from the wall portion 3k toward the wall portion 3m in the thickness direction of the housing 3A. The protrusion 31m extends along an outer surface of the wall portion 3n. That is to say, the protrusion 31m (coupling portion 30c) covers the wall portion 3n of the housing 3A from the outer side of the housing 3A. The coupling portion 30y is provided on the wall portion 3n. An internal threaded hole 30y1 as a portion to which the screw 10 as the coupling member is secured is provided on the coupling portion 30y. The screw 10 is inserted into the opening 31k from the outer side of the housing 3A so as to be coupled to the internal threaded hole 30y1. With this configuration, the coupling portions 30c and 30y are coupled to each other with the screw 10 as the coupling member.

In the first embodiment, the coupling portion 30y of at least one (in the first embodiment, the third member 3Md as an example) of the second member 3Rr and the third member 3Md is located at an inner position of the housing 3A with respect to the coupling portion 30c of the first member 3Fr, as an example. Therefore, in the first embodiment, the first member 3Fr is suppressed from moving from the end 3e side to the end 3c side (from the right side to the left side in FIG. 4) with respect to at least one (in the first embodiment, the second member 3Rr as an example) of the second member 3Rr and the third member 3Md with engagement of the coupling portions 30c and 30y in a state where the screw 10 is not coupled, as an example. It is to be noted that in the first embodiment, the first member 3Fr is not suppressed from moving from the end 3c side to the end 3e side (from the left side to the right side in FIG. 4) with respect to at least one (in the first embodiment, the second member 3Rr as an example) of the second member 3Rr and the third member 3Md with the engagement of the coupling portions 30e and 30h in the state where the screw 10 is not coupled. The coupling portion 30c is an example of a third coupling portion, and the coupling portion 30y is an example of a fourth coupling portion.

That is to say, in the first embodiment, the first member 3Fr is not suppressed from moving from the end 3c side to the end 3e side with respect to the second member 3Rr and the third member 3Md with both of the coupling of the coupling portions 30e and 30h and the coupling of the coupling portions 30c and 30y. However, in the first embodiment, the first member 3Fr is suppressed from moving from the end 3c side to the end 3e side with respect to the second member 3Rr and the third member 3Md with the screw 10 as the coupling member. With this configuration, the first member 3Fr and each of the second member 3Rr and the third member 3Md that constitute the housing 3A are coupled to each other and the first member 3Fr and each of the second member 3Rr and the third member 3Md can be suppressed from being deviated from each other with a relatively simple configuration without providing the coupling members such as the screws 10 on both of the ends 3c and 3e.

Furthermore, in the first embodiment, a head portion 10a of the screw 10 as the coupling member is covered by the battery 18 as a functional part so as to be hidden, as an example. Therefore, disadvantages due to exposure of the screw 10 are easily suppressed from occurring. As the disadvantages, the coupling of the coupling portions 30c and 30y with the screw 10 is easily released, and appearance is easily spoiled, for example. According to the first embodiment, there is an advantage that the number of parts can be reduced, and the like, in comparison with a case where the screw 10 as the coupling member is covered by a dedicated cap, as an example.

Furthermore, in the first embodiment, the screw 10 as the coupling member for coupling the coupling portions 30c and 30y is located at a side opposite to the display screen 4a with respect to the display device 4, as an example. Therefore, a length by which the housing 3A projects outward from a side surface 4c (edge) of the display screen 4a when seen from the front side can be made shorter in comparison with a case where the screw 10 overlaps with the display device 4 in the direction along the display screen 4a (the screw 10 is located in the normal line direction of the side surface 4c with respect to the display device 4), as an example. Therefore, a size of the housing 3A with respect to a size of the display device 4 is easily made smaller, as an example. In addition, the screw 10 extends in the direction along the display screen 4a (direction intersecting with the thickness direction of the housing 3A). Therefore, the thickness of the housing 3A is easily made smaller in comparison with a case where the screw 10 extends in the thickness direction of the housing 3A.

Furthermore, in the first embodiment, spaces g1 and g2 are provided between the screw 10 secured to at least any one (in the first embodiment, the third member 3Md as an example) of the second member 3Rr and the third member 3Md and the protrusion 31m (coupling portion 30c, first member 3Fr), as an example. That is to say, the head portion 10a of the screw 10 makes contact with the wall portion 3n and the spaces g1 and g2 are provided between the head portion 10a and the protrusion 31m. The space g1 is a space along the thickness direction of the housing 3A and the space g2 is a space in the direction along the display screen 4a. With this configuration, even when positional deviation between the (opening 31k of the) coupling portion 30c and the (internal threaded hole 30y1 of the) coupling portion 30y becomes larger due to accumulation of dimensional deviation or the like, the following state can be reliably realized. That is, even in such a case, a state where the screw 10 is secured to the internal threaded hole 30y1 and the first member 3Fr and at least one (in the first embodiment, the third member 3Md as an example) of the second member 3Rr and the third member 3Md are coupled to each other with the coupling portions 30c and 30y can be reliably realized. The first member 3Fr and at least one (in the first embodiment, the third member 3Md as an example) of the second member 3Rr and the third member 3Md are coupled to each other on the end 3e with the coupling of the coupling portions 30c and 30y in a movable manner in a range of the spaces g1 and g2. Furthermore, it can be said that the first member 3Fr and at least one (in the first embodiment, the third member 3Md as an example) of the second member 3Rr and the third member 3Md are connected to each other with allowance with the coupling of the coupling portions 30c and 30y. That is to say, according to the first embodiment, strain is easily suppressed from being generated on the housing 3A with coupling in the above state.

### Second Embodiment

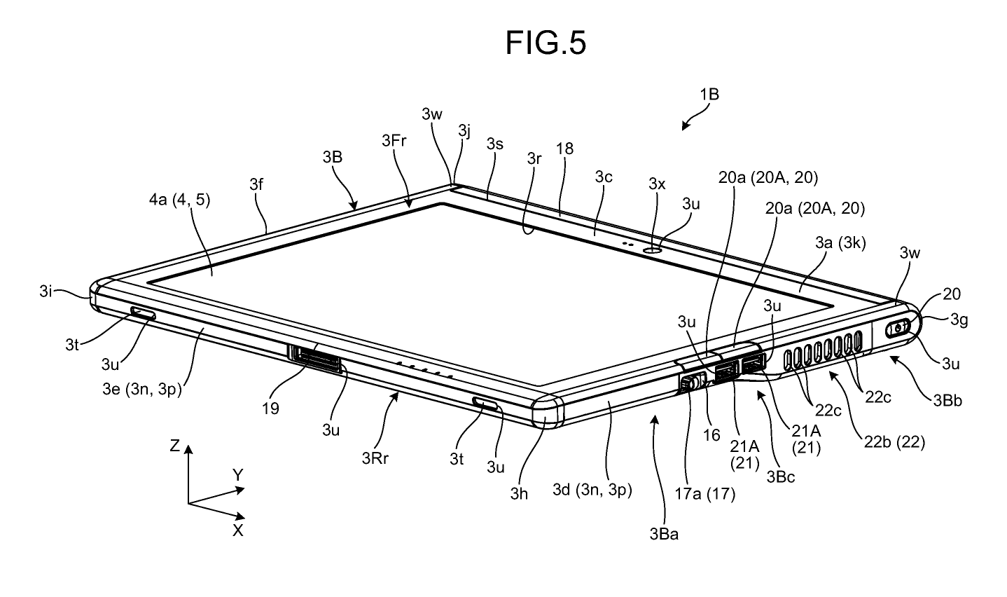

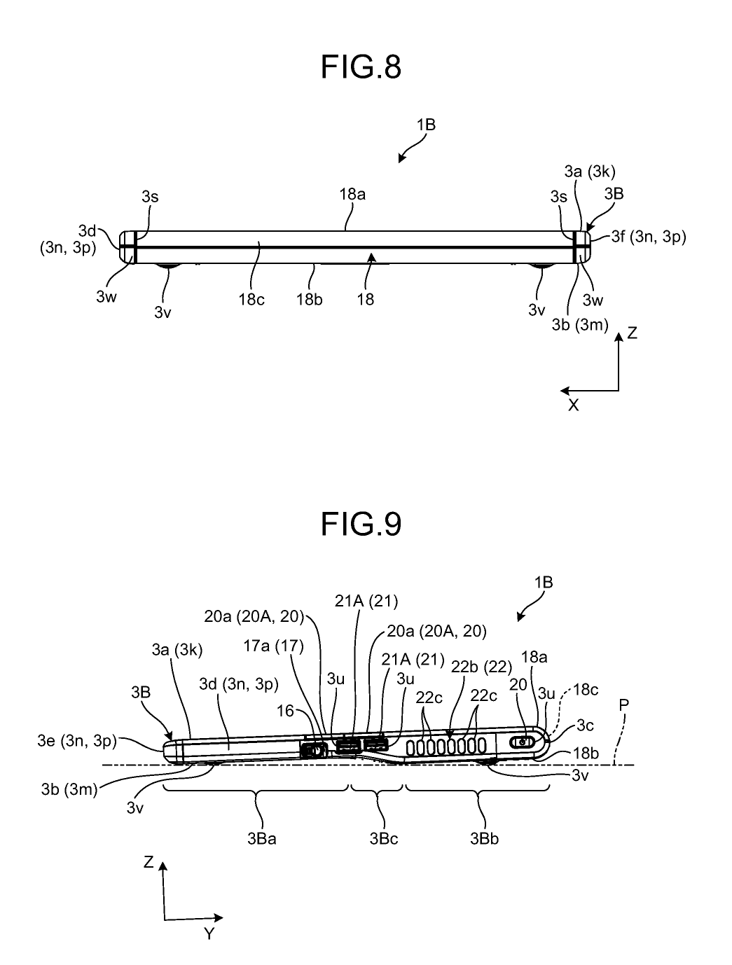

In the second embodiment, a housing 3B of an electronic apparatus 1B is configured to have a rectangular shape (in the second embodiment, a square shape as an example) when seen from the front side and the rear side, as illustrated in FIGS. 5 to 11, as an example. Furthermore, in the second embodiment, the housing 3B is configured to have a flattened box shape that is thin in the front-rear direction as illustrated in FIGS. 8 to 11, as an example. The housing 3B comprises the front surface 3a (front face, surface, first surface, first surface portion) and the back surface 3b (rear face, surface, second surface, second surface portion) at a side opposite to the front surface 3a. The front surface 3a and the back surface 3b are substantially parallel with each other. Furthermore, the housing 3B comprises the four ends 3c to 3f (sides, edges) and the four corners 3g to 3j (sharp portions, bent portions, ends) when seen from the front side, as illustrated in FIGS. 5, 8, to 11. The ends 3c and 3e are examples of long sides. The ends 3d and 3f are examples of short sides.

The housing 3B also comprises a wall portion 3k (first wall portion, first portion, plate, frame, front wall portion, frontal wall portion, top wall portion) comprising the front surface 3a, and a wall portion 3m (second wall portion, second portion, plate, rear wall portion, back wall portion, bottom wall portion) comprising the rear surface 3b. Each of the wall portions 3k and 3m is in a rectangular shape (in the embodiment, an oblong shape, as an example). The housing 3B also comprises four wall portions (third wall portions, third parts, plates, side wall portions, end wall portions, standing wall portions, stretched portions) 3n laid across and between the wall portion 3k and the wall portion 3m comprising side surfaces 3p (surface, circumferential surface, third surface). An opening 3r that is rectangular in shape is disposed on the wall portion 3k, as an example.

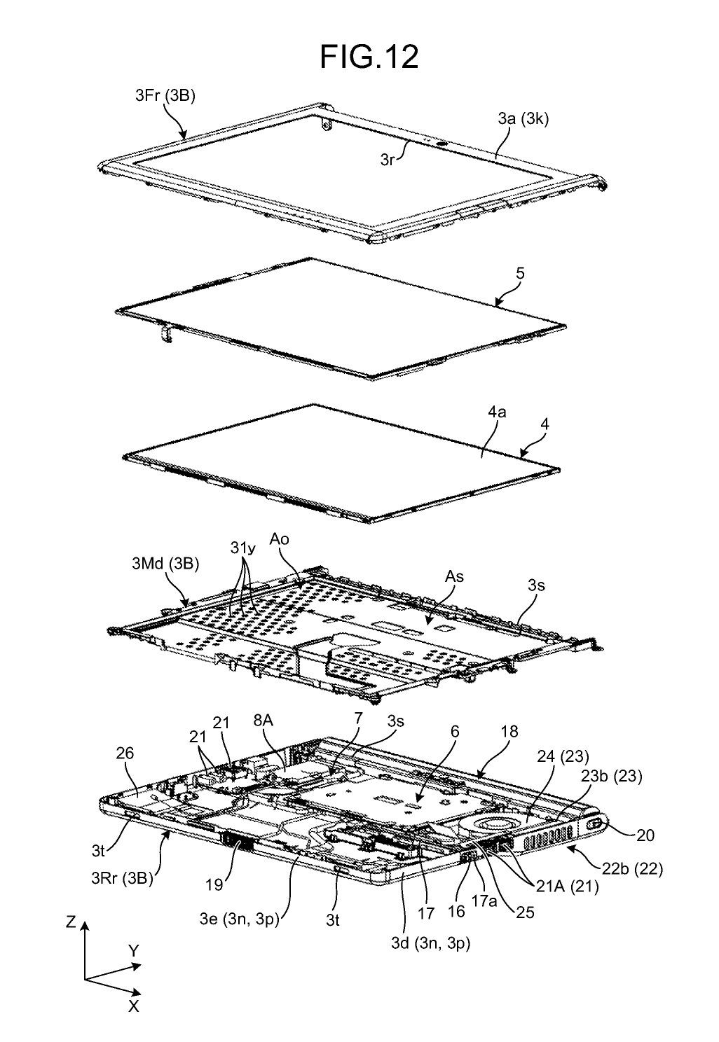

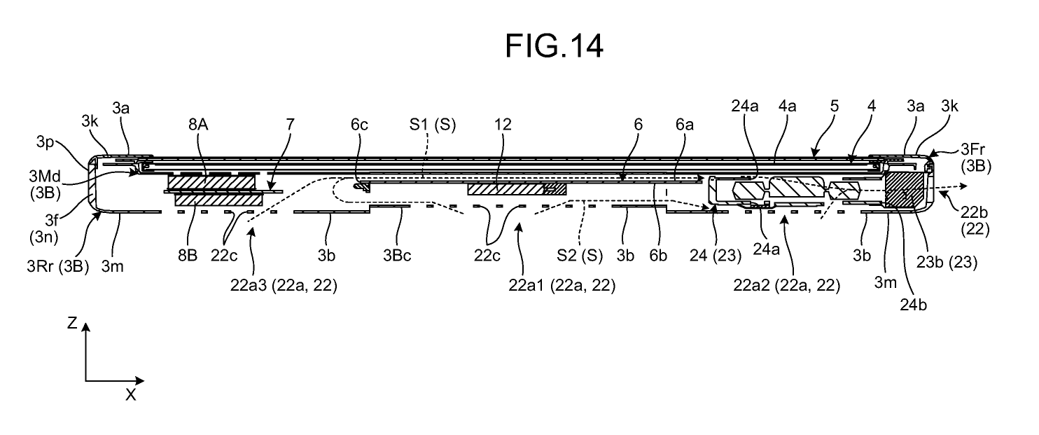

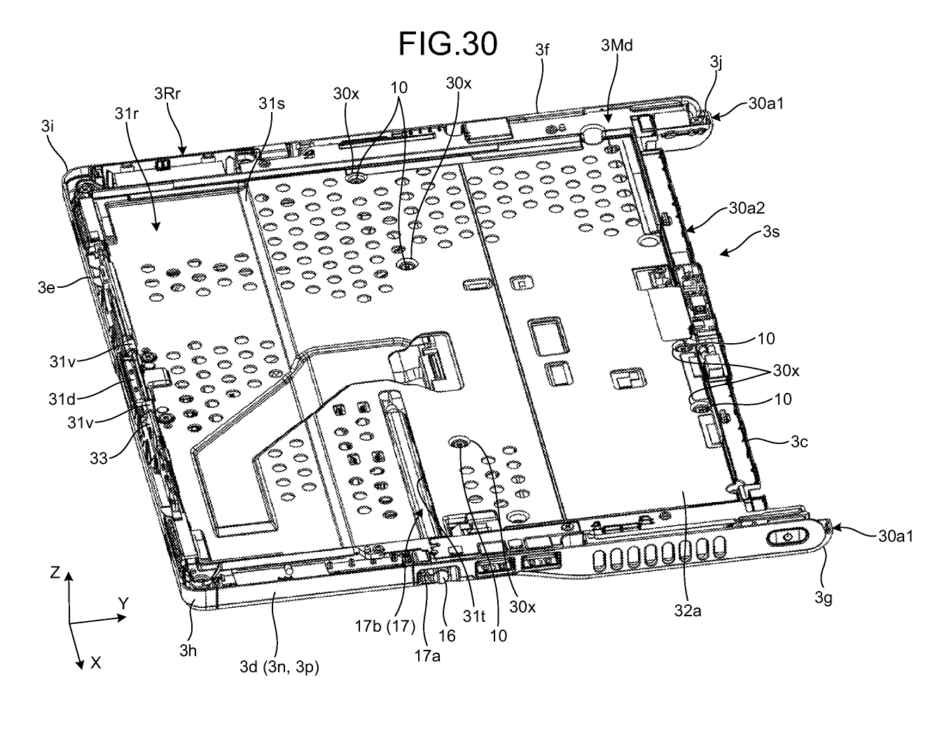

Furthermore, the housing 3B can be configured by combining a plurality of parts (divided members). In the second embodiment, the housing 3B comprises the first member 3Fr (first housing portion, first portion, front-side member, cover), and the second member 3Rr (second housing portion, second portion, back-side member, base, bottom), as an example. The first member 3Fr comprises at least the wall portion 3k. The second member 3Rr comprises at least the wall portion 3m. The wall portions 3n are comprised in at least one (for example, second member 3Rr) of the first member 3Fr and the second member 3Rr. Furthermore, in the second embodiment, the housing 3B comprises, in addition to the first member 3Fr and the second member 3Rr, the third member 3Md (third housing portion, third portion, intermediate member, separation member, barrier wall member, wall member, interposing member, inner plate, middle plate, middle frame) that is located between the first member 3Fr and the second member 3Rr as illustrated in FIGS. 12 and 14. A part of the wall portions 3n can be comprised in the third member 3Md. The housing 3B can be formed with a metal material, a synthetic resin material, or the like. As an example, the second member 3Rr and the third member 3Md can be formed with a material having relatively high rigidity (for example, metal material such as magnesium alloy). The first member 3Fr can be formed with a material having relatively low rigidity (material having rigidity that is lower than that of the second member 3Rr and the third member 3Md, for example, synthetic resin material). It is to be noted that wall portions (protrusions, protruding wall portions) such as ribs can be provided on the first member 3Fr, the second member 3Rr, and the third member 3Md. With the wall portions, rigidity of the housing 3B is easily made higher. Furthermore, an opening such as a through-hole can be provided on the third member 3Md. The housing 3B can be configured to be lightweight with the opening, as an example. In addition, flow of air in the housing 3B is easily ensured, as an example. It can be said that an assembly of the second member 3Rr and the third member 3Md (FIG. 30 or the like) is an example of a second housing portion.

Furthermore, in the second embodiment, as illustrated in FIGS. 9 and 11, the thickness of a first portion 3Ba that is at the lower side or the near side (side closer to a user) in a usage state while the lengthwise direction is set to a lateral direction is smaller than the thickness of a second portion 3Bb that is at the upper side or the far side (side farther from the user) in the above usage state, as an example. Therefore, in a state where the electronic apparatus 1B is placed on a placement surface P such as a desk for use, the height of the front surface 3a of the housing 3B and the display screen 4a from the placement surface P (horizontal surface) increases from the near side (lower side) to the far side (upper side). Therefore, according to the second embodiment, there is an advantage that the display screen 4a is made in a so-called tilt state for a user positioned at the left side in FIG. 9 (right side in FIG. 11) with respect to the electronic apparatus 1B and the user can easily observe the display screen 4a, as an example. An angle (obtuse angle side) between the display screen 4a and the placement surface P is preferably equal to or larger than 135° and smaller than 180° in the state as illustrated in FIGS. 9 and 11. In the second embodiment, a plurality of protrusions 3v (3v, 3v) are provided on the back surface 3b of the housing 3B, as an example. As is obvious from FIGS. 9 and 11, a distance between a front end of the protrusion 3v located on the second portion 3Bb and the display screen 4a in FIGS. 9 and 11 is longer than a distance between a front end of the protrusion 3v located on the first portion 3Ba and the display screen 4a in FIGS. 9 and 11. In the second embodiment, the (front end of the) protrusion 3v at the left side in FIG. 9 (right side in FIG. 11) is an example of a first contact portion and the (front end of the) protrusion 3v at the right side in FIG. 9 (left side in FIG. 11) is an example of a second contact portion.

The housing 3B also comprises a component receptacle 17 for holding a component 16 in a removable manner. In the embodiment, as an example, an opening 17a of the component receptacle 17 opens to the end 3d. The opening 17a is formed on the end 3d coming to the top in one of use positions and not coming to the bottom in a non-use position. Such an arrangement allows the opening 17a to come to the top in the use position. Therefore, as an example, the component 16 is better prevented from falling out of the component receptacle 17 by the action of the gravity. The component 16 is, specifically, a stylus, a stylus pen, or a pen, for example.

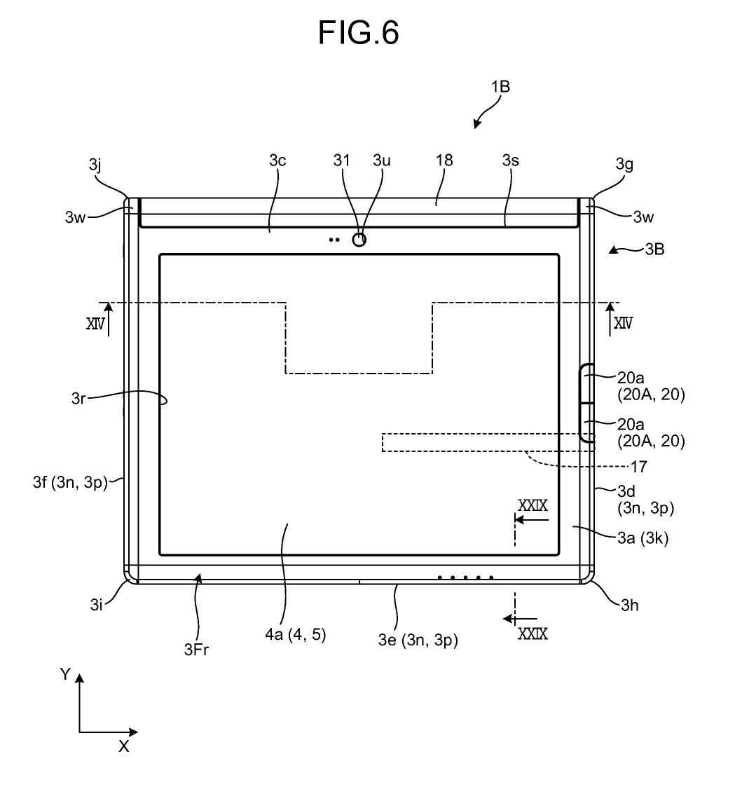

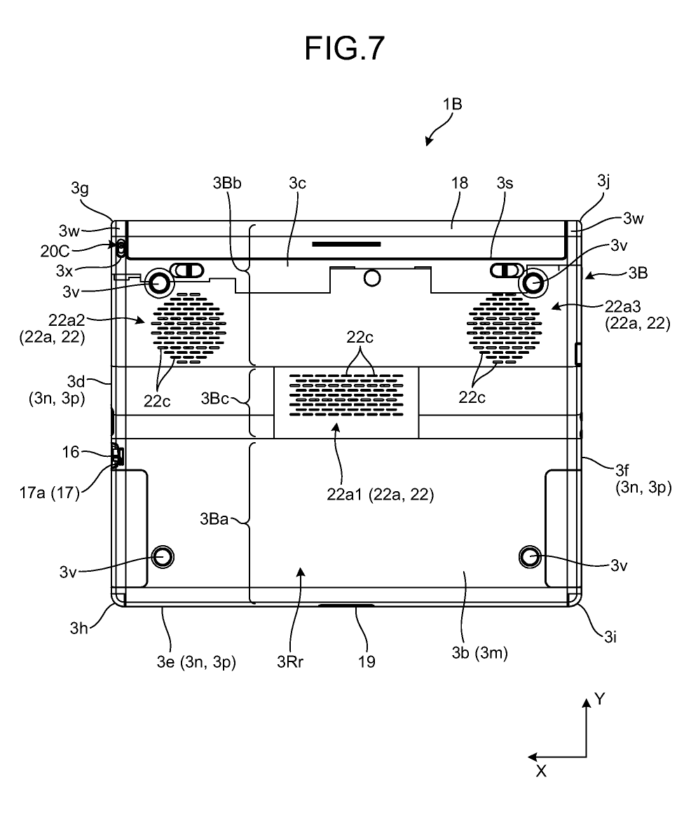

In the embodiment, as an example, as illustrated in FIGS. 5 and 6, a battery 18 (module, component, electric component, removable component, replacement component) and a display device 4 are not placed on top of each other in the thickness direction of the housing 3B, but are arranged side by side along a direction in perpendicular to the thickness direction (the direction along the front surface 3a or the rear surface 3b, the X direction or the Y direction; along the Y direction in the embodiment, as an example). Therefore, as an example, the thickness of the housing 3B can be reduced compared with the configuration in which the battery 18 and the display device 4 are placed on top of each other in the thickness direction of the housing 3B. Furthermore, as an example, the thickness of the battery 18 can be further increased easily compared with the configuration in which the battery 18 and the display device 4 are placed on top of each other in the thickness direction of the housing 3B. Therefore, the per-volume capacity of the battery 18 can be increased easily. In the embodiment, the housing 3B comprises the first section 3Ba having a smaller thickness, and the second section 3Bb having a larger thickness, as illustrated in FIGS. 5 and 7. A battery receptacle 3s (battery support) for holding the battery 18 is laid along the end 3c of the second section 3Bb having a larger thickness. Therefore, as an example, the thickness of the battery 18 can be increased more easily compared with a configuration in which the battery receptacle 3s is arranged in the first section 3Ba. Therefore, the per-volume storage capacity of the battery 18 can be increased easily.

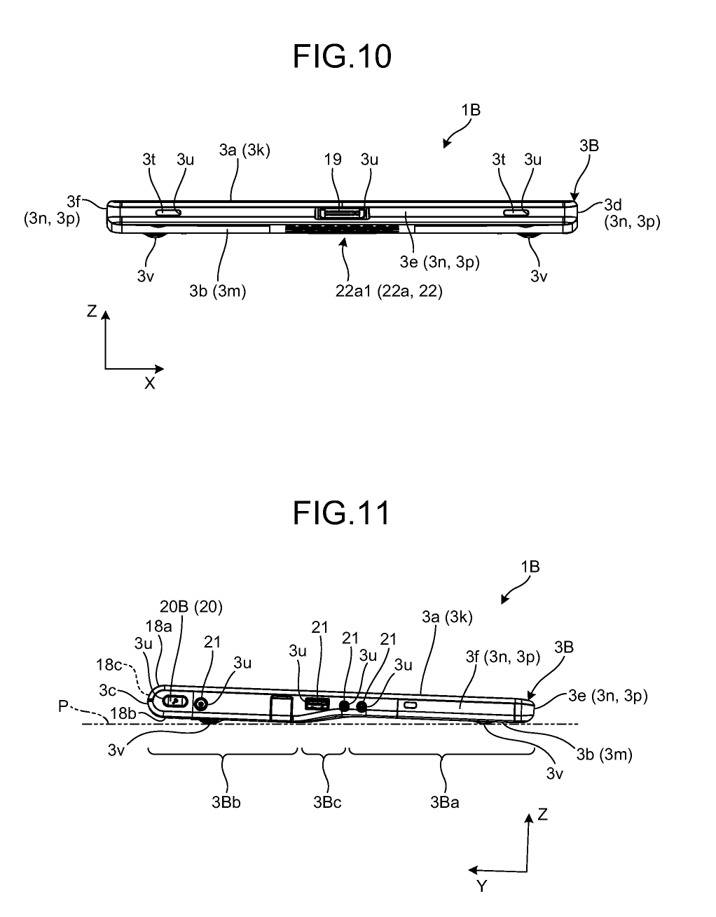

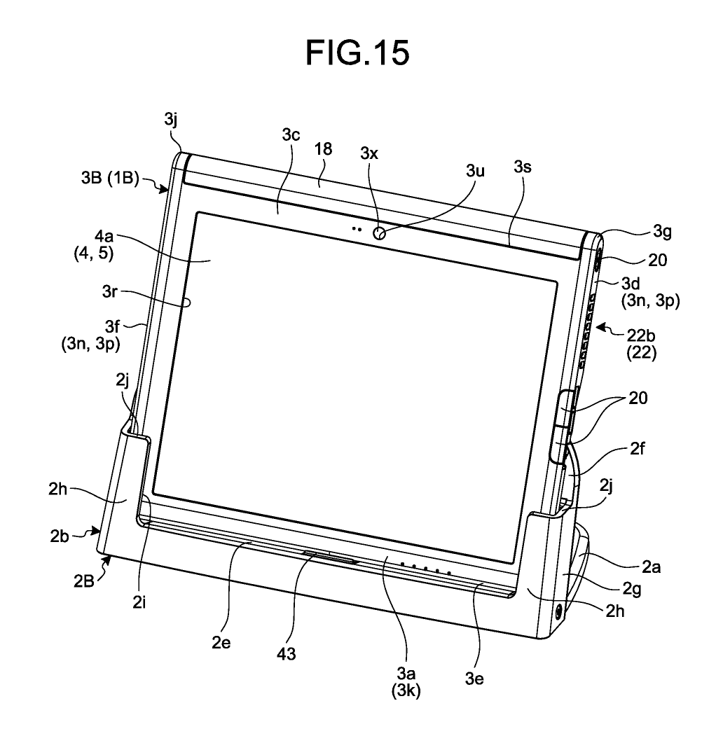

Furthermore, in the second embodiment, as illustrated in FIG. 15, the end 3e at the side opposite to the end 3c on which the battery accommodation portion 3s is provided is supported by a stand 2B, as an example. Therefore, an operator (user or the like) can attach the battery 18 to the housing 3B in a detachable manner in a state where the electronic apparatus 1B is supported by the stand 2B, as an example. Furthermore, a connector 19 connected to a connector (not illustrated) of the stand 2B is provided on the end 3e, as illustrated in FIGS. 7 and 10. Therefore, the battery accommodation portion 3s and the connector 19 are easy to be provided on the housing 3B without interfering with each other, as an example. It is to be noted that speaker covers 3t are also exposed on the end 3e. The connector 19 and the speaker covers 3t are exposed through openings 3u provided on the wall portion 3n on the end 3e. The connector 19 is an example of a first connector.

Furthermore, in the embodiment, as an example, operating modules 20 and connectors 21 are provided on the front surface 3a or the side surface 3p of the housing 3B, as illustrated in FIGS. 5, 6, 9, and 11. The operating modules 20 can be a push button, a push switch, a sliding switch, or a pointing device, for example. The connectors 21 are a connector for a power cable, a universal serial bus (USB) connector, and a connector for a headset or a microphone, for example. The operating modules 20 and the connectors 21 are respectively exposed through the openings 3u that are provided on the wall portions 3k and 3n on the housing 3B. Furthermore, a camera 3x(camera module, imaging apparatus) can be disposed on the front surface 3a.

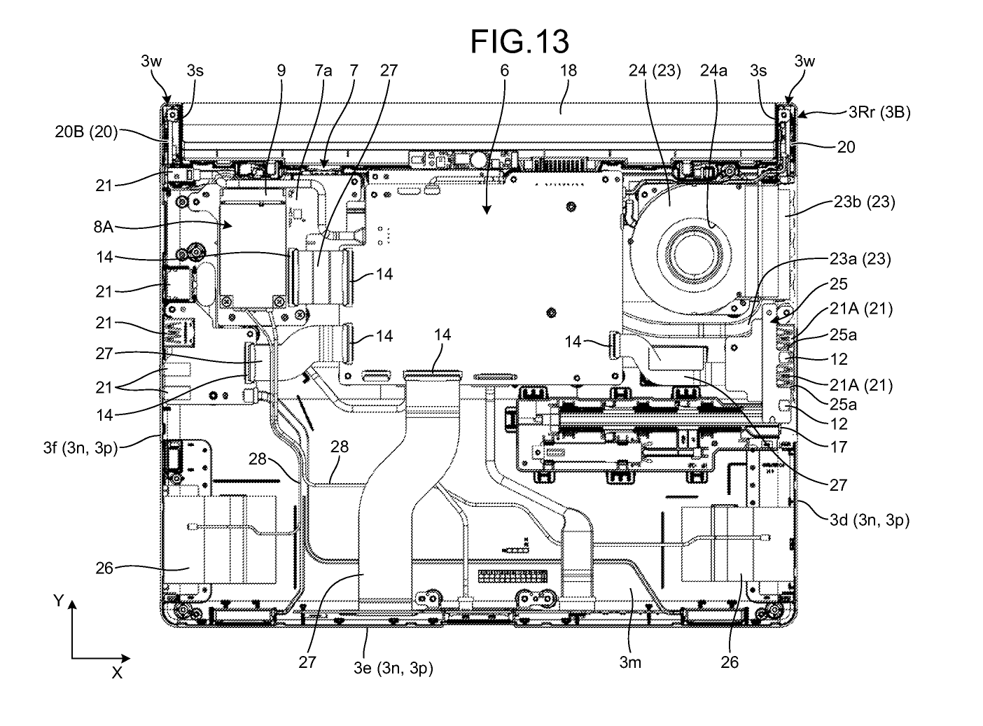

Furthermore, in the embodiment, as an example, vent holes 22 through which the air for cooling electronic components 12 (see FIG. 14, for example) is collected and discharged are provided on the rear surface 3b and the side surface 3p of the housing 3 as illustrated in FIGS. 5, 7, 9, 10, and 14. In the embodiment, as an example, inlets 22a through which the air is collected are provided on the rear surface 3b (the wall portion 3m), and an outlet 22b through which the air is discharged is provided on the side surface 3p (the wall portion 3n, the end 3d). In the embodiment, each of the inlets 22a and the outlet 22b is formed as a collection of a plurality of small holes 22c provided on each of the wall portions 3m and 3n. Because the protruding portions 3v are provided on the rear surface 3b, even if the rear surface 3b is placed on the setting surface P as illustrated in FIGS. 9 and 11, the inlets 22a are not blocked. Furthermore, in the embodiment, a tilted section 3Bc is provided at a boundary area between the thin first section 3Ba and the thick second section 3Bb of the housing 3B. An inlet 22a1 that is one of the inlets 22a is provided on the rear surface 3b of the tilted section 3Bc, as illustrated in FIG. 7. Because the distance between the tilted section 3Bc and the setting surface P is larger than the distance between other parts and the setting surface P, as illustrated in FIGS. 9 and 11, the flow resistance of the air at the inlet 22a1 provided on the tilted section 3Bc can be better reduced easily, and therefore, the cooling efficiency can further be increased easily. Furthermore, in the embodiment, because the inlet 22a is provided in plurality, even if any one of the inlets 22a is blocked for some reason, as an example, the air can be collected through the other inlets 22a into the housing 3B. Therefore, the cooling performance is not lost easily. The housing 3B may be cooled by a cooling mechanism 23 (see FIGS. 13 and 14, for example), or may be naturally cooled (by convection cooling).

In the embodiment, as an example, the display device 4 (display module, display, panel) is housed between the first member 3Fr and the third member 3Md, as illustrated in FIGS. 12 and 14. The display screen 4a facing the front surface 3a of the display device 4 is exposed through the opening 3r to the front side (outside) of the housing 3B. Therefore, a user can see the display screen 4a through the opening 3r from the front side. The display device 4 is in a rectangular shape (in the embodiment, an oblong shape, as an example) viewed from the front. Furthermore, the display device 4 is in a flat parallelepiped shape, being thin in the front-back direction. The display device 4 is a liquid crystal display (LCD) or an organic electro-luminescent display (GELD), for example.

Furthermore, in the embodiment, as an example, an input operation panel 5 (touch panel, touch sensor, operation panel, as an example) that is transparent, relatively thin, and rectangular in shape is provided on the front side (frontal side, the side of the wall portion 3k) of the display device 4. The input operation panel 5 covers the display screen 4a. An operator (e.g., a user) can perform an inputting process by performing an operation, such as touching, pressing, or rubbing, on the input operation panel 5 using a hand, a finger, the component 16 (stylus), and the like, or moving a hand, a finger, a stylus, and the like near the input operation panel 5. Furthermore, the light output from the display screen 4a of the display device 4 passes through the input operation panel 5, and is emitted toward the front side (outer side) of the housing 3B through the opening 3r on the wall portion 3k. The input operation panel 5 is an example of an input module.

In the embodiment, as an example, a plurality of boards 6, 7, and 25 are installed on the rear side of the display device 4 (back side, behind side, the side near the wall portion 3m, the side opposite to the display screen 4a). In the embodiment, as an example, the boards 6, 7, and 25 are installed between the second member 3Rr and the third member 3Md in the housing 3B, as illustrated in FIGS. 12 and 14. The boards 6, 7, and 25 are placed at positions different from each other, and are laid in parallel with the display device 4. Furthermore, the boards 6, 7, and 25 are provided in a manner separated from the wall portions 3k, 3m, and 3n, for example, that is, provided so that a space is formed between the boards and the wall portions 3k, 3m, and 3n, for example. The boards 6, 7, and 25 are provided side by side along the display device 4, so as not to be placed on top of each other in the thickness direction of the housing 3B. The boards 6, 7, and 25 are also fixed to the housing 3B with couplers such as screws.

Furthermore, in the embodiment, as an example, the electronic components 12 provided in plurality (see FIG. 14; only partially illustrated in FIG. 14) such as a central processing unit (CPU), a graphic controller, a power circuit component, a platform controller hub (PCH), a memory slot connector, an LCD connector, an input/output (I/O) connector, a power coil, an element, a connector, and the like can be implemented on the board 6 (first board, first circuit board, control board, main board). The electronic components 12 comprise heating elements. The electronic component 12 (heating element) that generates a large amount of heat can have the cooling mechanism 23. The cooling mechanism 23 comprises a heat sink (heat receiving module, not illustrated), a heat pipe 23a, a heat dissipating module 23b, and a fan 24. The board 6 and the electronic components 12 make up at least a part of a controlling circuit (not illustrated). The controlling circuit can comprise a video signal processing circuit, a tuner, a high-definition multimedia interface (HDMI) signal processor, an audio video (AV) input terminal, a remote controller signal receiver, a controller, a selector, an on-screen display interface, a storage module (e.g., a read-only memory (ROM), a random access memory (RAM), a hard disk drive (HDD), and a solid state drive (SSD)), and a voice signal processing circuit. The controlling circuit controls video outputs (e.g., moving images or still images) from the display screen 4a of the display device 4, sound outputs from a speaker (not illustrated), and light emissions from a light emitting diode (LED) (not illustrated). The display device 4, the speaker, the LED, and the like are examples of an output module.

Furthermore, in the second embodiment, as is obvious from FIGS. 9, 11, and 13, the substrate 6 and 7 and the cooling mechanism 23 are located on the thick second portion 3Bb of the housing 3B, as an example. Therefore, as an example, a space is easily ensured to be larger in comparison with a case where the substrate 6 and 7 and the cooling mechanism 23 are located on the thin first portion 3Ba, so that a cooling effect by airflow flown by the fan 24 of the cooling mechanism 23 is easily obtained. Furthermore, in the second embodiment, the fan 24 and the heat dissipater 23b are provided on the corner 3g to which the end 3c and the end 3d are connected, as an example. The corner 3g is located at the upper side in a defined (controlled) usage state. Accordingly, the fan 24 and the heat dissipater 23b can be arranged at the upper side in the housing 3B without depending on a usage posture of the electronic apparatus 1B, as an example. Therefore, heat is difficult to be retained in the housing 3B, as an example. It is to be noted that the fan 24 and the heat dissipater 23b are provided so as to be adjacent to a discharge port 22b.

Furthermore, in the second embodiment, the substrate 7 is provided at a position of sandwiching the substrate 6 between the substrate 7 and the cooling mechanism 23 (a position at which the substrate 7, the substrate 6 and the cooling mechanism 23 are arranged in this order on the second portion 3Bb), as an example. With this configuration, the air sucked from the outside hits the substrate 7 before reaching the position of the substrate 6. Therefore, heat dissipation efficiency of the substrate 7 is easily higher, as an example. Furthermore, the substrate 7 on which modules 8A, 8B are mounted is located at a position opposite to the cooling mechanism 23 as one heavy-weight matter with respect to the substrate 6 that has a relatively heavyweight among parts in the housing 3B and is located at a center of the housing 3B. Accordingly, weight balance of the electronic apparatus 1B is improved, as an example. Therefore, a user can carry the electronic apparatus 1B more easily, as an example.

Furthermore, in the embodiment, as an example, the wall portion 3m of the housing 3B comprises an inlet 22a2 arranged near the fan 24, an inlet 22a3 arranged on the opposite side of the inlet 22a2 with respect to the board 6, and the inlet 22a1 arranged nearer to the electronic components 12, which is a heating element, than the inlets 22a2 and 22a3, as illustrated in FIGS. 7 and 14. By providing the inlet 22a2, the air flow is permitted to flow through the housing 3B more efficiently. Furthermore, an air flow S collected through the inlet 22a3 is divided into an air flow S2 flowing toward the fan 24 along a second surface 6b that is the rear surface of the board 6, and an air flow S1 flowing by passing through outside (flowing around, bypassing) an end 6c of the board 6 located opposite side of the fan 24 along a first surface 6a that is the front side of the board 6 toward the fan 24. Therefore, it is possible to cool the electronic components 12 (heating elements) implemented on both sides of the first surface 6a and the second surface 6b of the board 6.

Furthermore, in the embodiment, as an example, as illustrated in FIG. 13, the board 7 and the modules 8A and 8B are laid along the display device 4. Furthermore, the electronic components 12 are implemented on the board 25. A flexible cable 27 is also housed in the housing 3B. The flexible cable 27 electrically connects the boards 6, 7, and 25, the display device 4, the connector 19, and the like. The flexible cable 27 is, for example, a flexible printed wiring board or a flat cable.

A plurality of antennas 26 is also housed in the housing 3B, as illustrated in FIG. 13. In the embodiment, the antennas 26 connected to a communication module (for example, the module 8B) are provided in a manner separated from each other. In the embodiment, as an example, one of the antennas 26 is disposed near the end 3d and the end 3e (near the corner 3h) of the housing 3B, and the other antenna 26 is disposed near the end 3e and the end 3f (near the corner 3i) of the housing 3B. In this manner, as an example, the space diversity of the antennas 26 can be realized. The antennas 26 and the module 8B are electrically connected via a cable 28. Functions can be divided between the antennas 26 and 26, e.g., using one of the antennas 26 for transmissions and receptions, and using the other antenna 26 only for transmissions. Alternatively, one of the antennas 26 can be used as a backup of the other antenna 26.

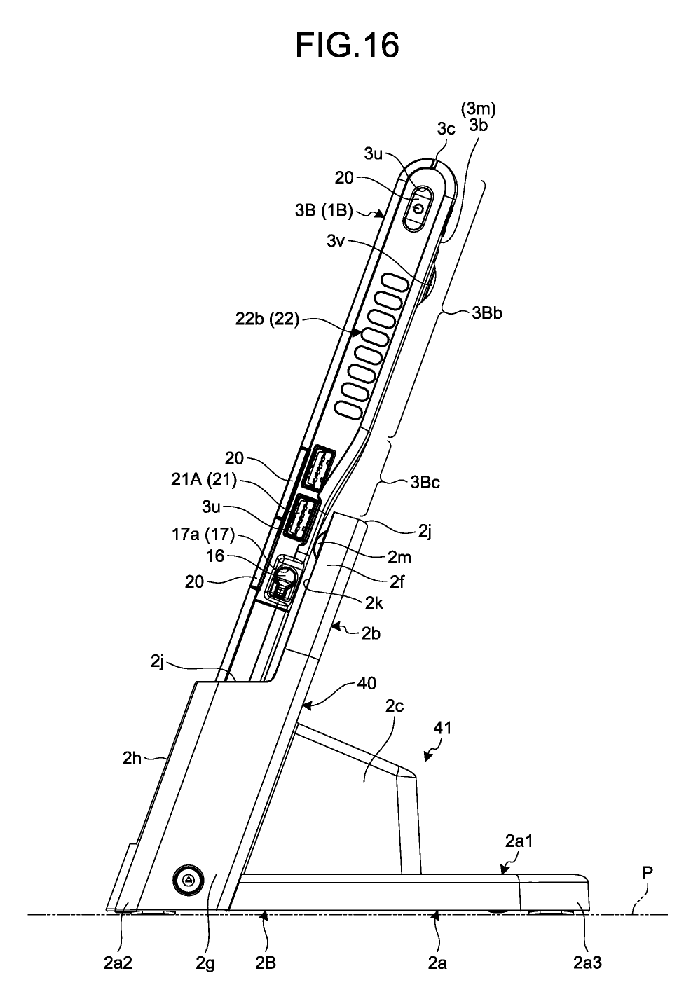

In the second embodiment, as illustrated in FIGS. 15 and 16, the stand 2B comprises a first supporting portion 2a and a second supporting portion 2b, as an example. The first supporting portion 2a is placed on the placement surface P (see FIG. 16) and functions as a foundation (table portion, bottom portion, lower portion, ground portion, base, base portion, placement portion, leg portion, leg, falling suppression portion, suppression portion). The second supporting portion 2b protrudes on the placement surface P from the (bottom portion of the) first supporting portion 2a and holds the housing 3B of the electronic apparatus 1B in a predetermined posture (position). That is to say, the second supporting portion 2b functions as a holding portion (erected portion, longitudinal portion, upper portion, reception portion, bearing portion, cover portion, abutment portion, contact portion, guide portion). It is to be noted that the first supporting portion 2a and the second supporting portion 2b need not be clearly separated from each other as parts and may be sites of a part. Furthermore, in the second embodiment, the stand 2B comprises a protrusion 2c, as an example. The protrusion 2c is positioned between the first supporting portion 2a and the second supporting portion 2b and protrudes to the upper side of the first supporting portion 2a and the back side of the second supporting portion 2b. The protrusion 2c has a function as a part accommodation portion 41 that accommodates a part. At the same time, the protrusion 2c is interposed between the first supporting portion 2a and the second supporting portion 2b so as to function as a supporting portion that supports the second supporting portion 2b. The stand 2B, the first supporting portion 2a, the second supporting portion 2b, and the protrusion 2c are examples of a supporting portion that supports the electronic apparatus 1B. The first supporting portion 2a, the second supporting portion 2b, and the protrusion 2c can be embodied in various specifications (shape, configuration, number, and the like). The stand 2B is mechanically and electrically connected to the electronic apparatus 1B located at a predetermined position (attachment position, holding position, placement position) of the stand 2B.

The stand 2B can provide various functions relating to the attached electronic apparatus 1B. The stand 2B can function as a stand for erecting the display screen 4a, for example. In this case, the stand 2B can have a function of variably setting an angle of the display screen 4a (posture of the electronic apparatus 1B). This will be described later. Furthermore, the stand 2B can function as a charging device of the electronic apparatus 1B, for example. In this case, the stand 2B can function as a wired charging device that is electrically connected to the electronic apparatus 1B. Alternatively, the stand 2B can function as a charging device that performs non-contact charging (wireless power supply). In this case, a non-contact charging module is provided on the second supporting portion 2b, as an example. The stand 2B can function as a connector portion (hub for connector, relay device for data, signal, and the like) that increases connecters to be electrically connected to the electronic apparatus 1B, for example. Furthermore, the stand 2B can function as a speaker of the electronic apparatus 1B, for example. In addition, the stand 2B can also have a cooling function of cooling the electronic apparatus 1B, for example. In this case, an airflow path, a fan, and the like are provided in a housing 40 of the stand 2B so as to support or accelerate cooling of the electronic apparatus 1B by the air flowing through the airflow path, as an example. In addition, the airflow path can comprise openings facing the airflow ports 22 of the electronic apparatus 1B. Furthermore, the stand 2B may comprise a cooling module facing the electronic apparatus 1B, as an example. Moreover, the stand 2B can have a function of an AC adaptor, for example.

Furthermore, in the second embodiment, the stand 2B comprises a hollow configuration at least partially, as an example. The stand 2B comprises the housing 40 and accommodates at least a part of various parts (not illustrated) such as a substrate, a connector, an electronic part, and a harness in the housing 40. The housing 40 can be formed with a synthetic resin material or a metal material (in the second embodiment, a synthetic resin material as an example). Furthermore, in the second embodiment, a frame (frame member, skeletal member, member having high rigidity, rigid member, reinforcing member, not illustrated) is provided in the housing 40, as an example. The frame can be formed with a metal material or a synthetic resin material (in the second embodiment, a metal material as an example). In addition, in the second embodiment, a substrate, a connector, and an electronic part provided on the substrate, and the like are accommodated in the part accommodation portion 41 that is a part of the housing 40 and is configured as the protrusion 2c, as an example.

In the second embodiment, as illustrated in FIGS. 15 and 16, the first supporting portion 2a is thin when seen from the side along the placement surface P (line of sight in FIG. 16), exhibits a rectangular (trapezoidal shape) appearance when seen from a plane perpendicular to the placement surface P, and is configured into a flattened shape (plate shape, wall shape) along the placement surface P. Furthermore, in the second embodiment, the second supporting portion 2b protrudes in the direction of slightly falling toward the back side (back side in a state where the electronic apparatus 1B is attached, end 2a3 side at the side opposite to an end 2a2) from the perpendicular direction from the end 2a2 of the first supporting portion 2a, as an example. As illustrated in FIGS. 15 and 16, the second supporting portion 2b holds (support, receive, bear) a part of an end (in the second embodiment, the end 3e as an example) of the housing 3B of the electronic apparatus 1B. To be more specific, the second supporting portion 2b holds a part of the end so as to surround (cover) the part of the end from each direction except a direction (in the second embodiment, the upper direction as an example) in which the electronic apparatus 1B is attached (inserted) at a predetermined position (holding position, holding region), that is, from the lower side, back side, lateral side (left side and right side), and front side. Furthermore, a portion along the end 3e (see FIGS. 1 to 7) can be also covered by the second supporting portion 2b. In addition, the second supporting portion 2b also functions as a guide for guiding the housing 3B of the electronic apparatus 1B to the predetermined position when the electronic apparatus 1B is moved (slid, displaced, inserted, attached) to the predetermined position of the stand 2B. That is to say, the second supporting portion 2b is an example of a guiding portion (guide portion, slide portion, rail portion). In the second embodiment, the second supporting portion 2b comprises wall portions 2e to 2h, as an example. The wall portion 2e (first wall, first wall portion, bottom wall portion, lower wall portion) is located at a lower side of the housing 3B held at the predetermined position and covers the housing 3B from the lower side. The wall portion 2f (second wall, second wall portion, back wall portion, rear wall portion) is located at the back side of the housing 3B and covers the housing 3B from the back side (back side, back surface side, rear surface side, rear side). The wall portions 2g (third walls, third wall portions, side wall portions) are located at the lateral sides of the housing 3B and cover the housing 3B from the lateral sides. The wall portion 2h (fourth wall, fourth wall portion, front wall portion) is located at the front side of the housing 3B and covers the housing 3B from the front side. The wall portion 2e can be also configured as a part of the first supporting portion 2a.

Furthermore, in the second embodiment, the stand 2B covers the electronic apparatus 1B in a state where functional parts of the electronic apparatus 1B are exposed or in a state where the functional parts are communicated with periphery of the stand 2B, as an example. In the embodiment, as illustrated in FIG. 15, an opening 2i is provided on the second supporting portion 2b so as to correspond to a front portion of the electronic apparatus 1B, as an example. The opening 2i can be provided as a cutout, a through-hole, or the like (in the embodiment, a cutout as an example). That is to say, in the second embodiment, a portion that is along the ends 3d and 3f located at both of left and right sides of the front surface 3a of the housing 3B and does not overlap with the display screen 4a and the opening 3r is covered by the (wall portion 2h of the) second supporting portion 2b in a posture where the electronic apparatus 1B is attached to the stand 2B. With this configuration, visibility of the display screen 4a is easily ensured, as an example. It is to be noted that the portion may be covered by a member (for example, member different from second supporting portion 2b, first supporting portion 2a, a part of housing 40, and housing 40) that covers the end 3e located at the lower side of the front surface 3a of the housing 3B.

Furthermore, in the second embodiment, the stand 2B holds the electronic apparatus 1B in a state where the airflow ports 22 provided on the housing 3B of the electronic apparatus 1B are exposed, as an example. As illustrated in FIGS. 7, 9, and 10, the airflow ports 22 are provided on the second portion 3Bb and an inclined portion 3Bc of the housing 3B. Furthermore, as is obvious from FIGS. 7, 9, 11, and 15, the airflow ports 22 are located at the upper side with respect to ends 2j (edges, sides) at the upper side of each part of the second supporting portion 2b and are exposed without being covered by the stand 2B. Therefore, the obstruction by the stand 2B against air (airflow) flowing through the airflow ports 22 is easily suppressed as an example. Furthermore, the openings 3u for the connectors 21 that are provided on the housing 3B, the opening 17a of the part accommodation portion 17 that accommodates the part 16, the opening 3u for the operation module 20, and the like are also exposed. Therefore, in the second embodiment, the obstruction by the stand 2B against approach or operation by a part, or a hand or a finger to/on the openings 3u and 17a is easily suppressed, as an example. In addition, with the above configuration, the second portion 3Bb of the housing 3B as an example of a region on which a heat generation amount is large in the housing 3B is exposed from the stand 2B. Therefore, heat dissipation performance is easily larger in comparison with a case where the second portion 3Bb is covered by the stand 2B, as an example. Furthermore, cooling efficiency is easily higher, as an example.

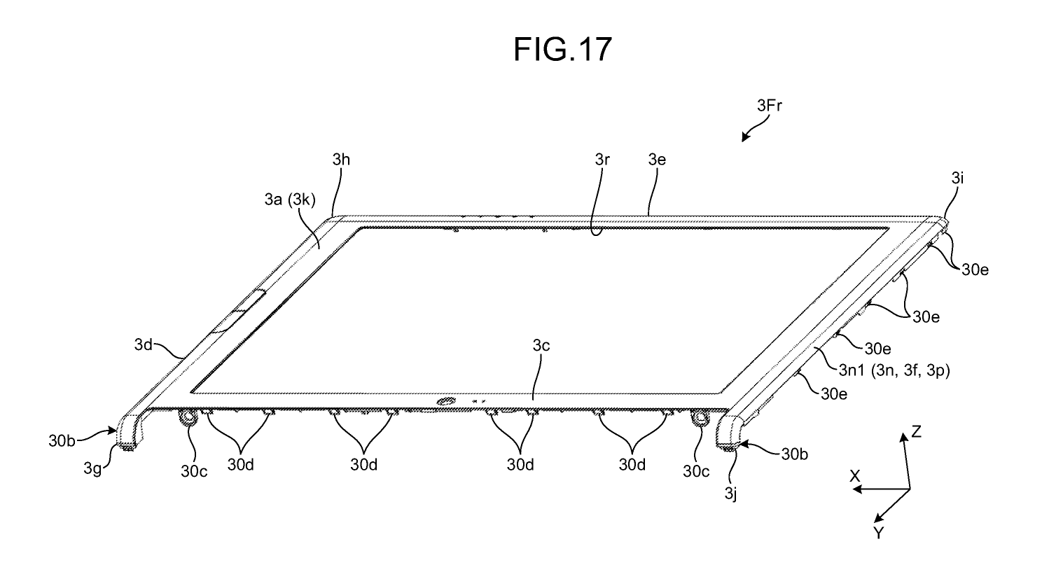

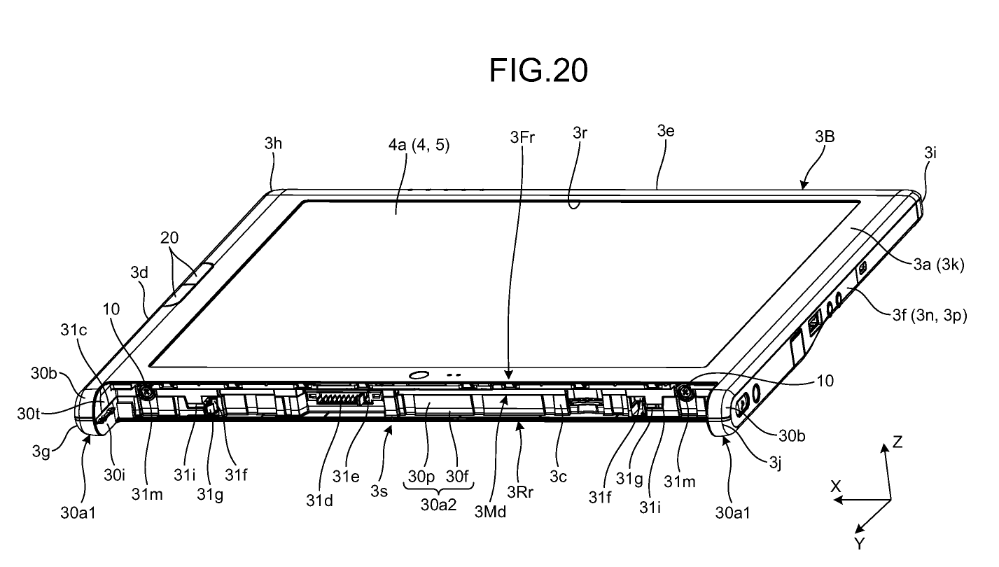

Furthermore, in the embodiment, as an example, as illustrated in FIG. 17, the first member 3Fr (first housing member) is formed in a rectangular (in the embodiment, an oblong shape, as an example) and frame-like shape viewed from the front and viewed from the rear. Specifically, the first member 3Fr comprises wall portions 3k and 3n1 (3n). The wall portions 3n1 (3n) are kept standing from the wall portion 3k on the perimeter of the wall portion 3k. The opening 3r is formed at the center of the first member 3Fr. The wall portion 3k that is a peripheral part of the opening 3r and the front surface 3a is structured in a band-like and plate-like shape. The first member 3Fr also comprises protrusions 30b. First supports 30a1 (see FIG. 20) located at the respective ends of the battery receptacle 3s in the longitudinal direction are respectively covered by the protrusions 30b from the front side. Each of the protrusions 30b is continuous from the wall portion 3k and the front surface 3a, and protrudes in the direction in which corresponding one of the end 3d and the end 3f extends. The tip side of each of the protrusions 30b is curved toward the wall portion 3m and the rear surface 3b (see FIGS. 9 and 7) to the outside of the housing 3B in a convexed arc-like shape, and is formed as a part of the end 3c and the side surface 3p. As illustrated in FIG. 12, the first member 3Fr covers the edges (peripheral parts) of the display device 4 and the input operation panel 5 from the front side. Therefore, the first member 3Fr is an example of a bezel (front bezel). Furthermore, the first member 3Fr is exposed except for a part facing the battery 18 (a part at (along) the end 3c). In other words, the first member 3Fr is an example of a shell.

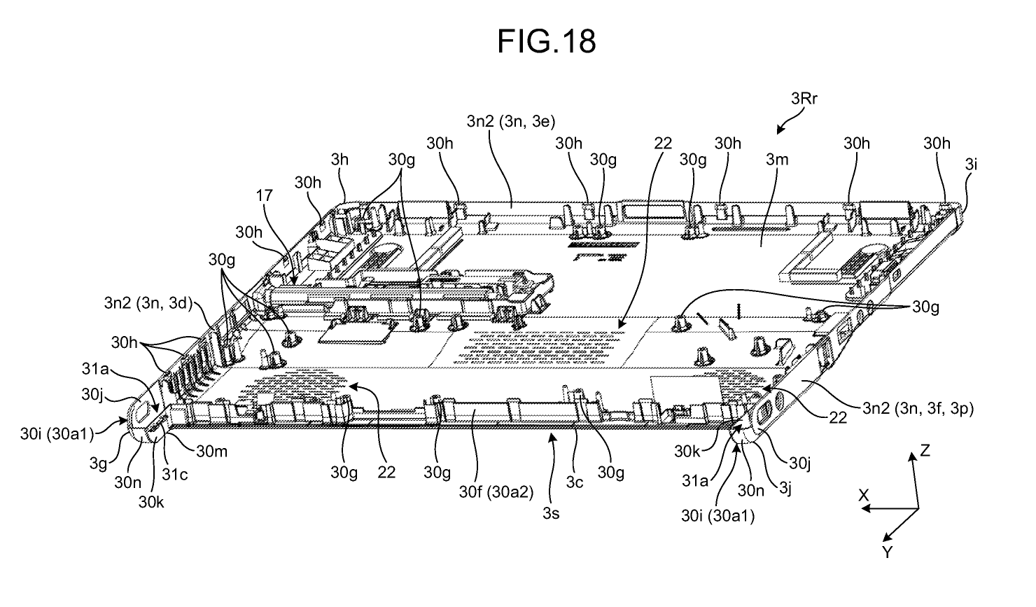

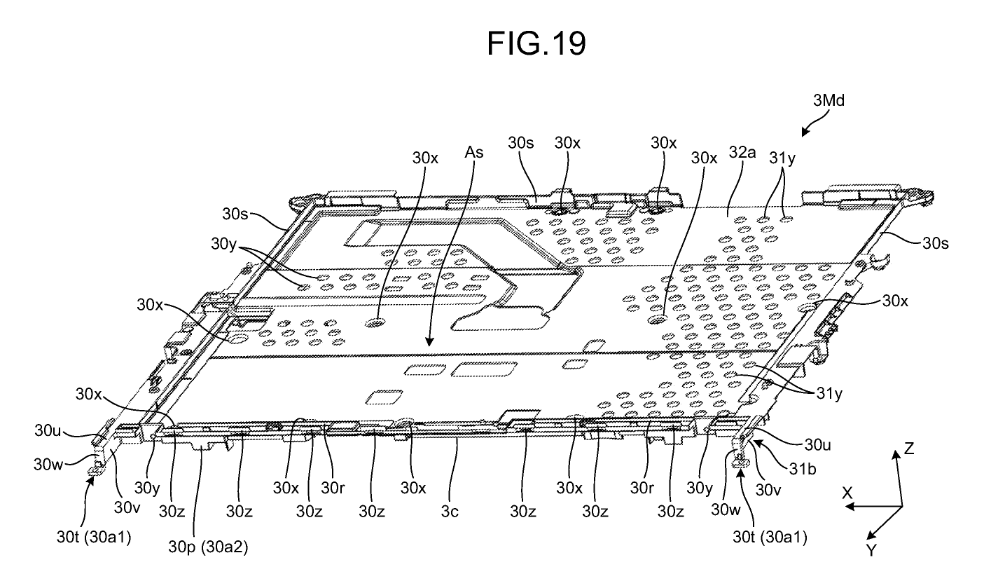

The first member 3Fr comprises coupled portions 30c, 30d, and 30e that are disposed along the outer perimeter of the first member 3Fr and are coupled to the other housing member (the second member 3Rr or the third member 3Md). The coupled portions 30c and the coupled portions 30d are disposed on a part of the first member 3Fr extending along the end 3c where the battery receptacle 3s is arranged. Each of the coupled portions 30c is formed as an opening (in the embodiment, a through-hole, as an example) through which a coupler, such as a screw 10, is inserted. The coupled portions 30c are respectively coupled to coupled portions 30y disposed on the other housing member (in the embodiment, the third member 3Md, as an example) via couplers such as the screws 10 (see FIG. 19). The coupled portions 30d (engaged portions) are respectively engaged with and coupled to coupled portions 30z (engaged portions, see FIG. 19) disposed on the other housing member (in the embodiment, the third member 3Md, as an example). The coupled portions 30e are disposed on each of the ends 3d, 3e, and 3f, but not on the end 3c of the first member 3Fr. The coupled portions 30e (engaged portions) are engaged with and coupled to coupled portions 30h (engaged portions, see FIG. 18) disposed on the other housing member (in the embodiment, the second member 3Rr, as an example). The coupled portions 30e are examples of a first engaged portion. The coupled portions 30h are examples of a second engaged portion.

Furthermore, in the embodiment, as an example, as illustrated in FIG. 18, the second member 3Rr (second housing member) is formed in a rectangular shape (in the embodiment, an oblong shape, as an example) viewed from in the front and viewed from the rear. The second member 3Rr as a whole is configured in a plate-like form. Specifically, the second member 3Rr comprises the wall portion 3m, wall portions 3n2 (3n), and a wall portion 30f. The wall portions 3n2 (3n) and 30f are kept standing from the wall portion 3m on the perimeter of the wall portion 3m. The wall portion 30f is structured as a part of the battery receptacle and a part of a battery support (second support 30a2), and faces the battery 18. The second member 3Rr is exposed except for a part facing the battery 18 (a part at (along) the end 3c). In other words, the second member 3Rr is an example of the shell.

Coupled portions 30g that are coupled to the other housing member (the first member 3Fr or the third member 3Md) are disposed on the inner surface of the wall portion 3m in the housing 3B. The coupled portions 30g are coupled to respective coupled portions 30x(see FIG. 19) disposed on the other housing member (in the embodiment, as an example the third member 3Md, as an example) via couplers such as the screws 10. Each of the coupled portions 30g is formed as a protrusion protruding from the wall portion 3m toward inside of the housing 3B, and has a fixed portion to which the coupler is fixed (e.g., a hole with an internal screw). The wall portion 3m also comprises the component receptacle 17 in which the component 16 is received. The coupled portions 30h are disposed on the wall portions 3n, but not on the wall portion 30f. The coupled portions 30h (engaged portions) are engaged with and coupled to the respective coupled portions 30e (engaged portions, see FIG. 17) disposed on the other housing member (in the embodiment, the first member 3Fr, as an example).

The second member 3Rr comprises protrusions 30i each of which is a part of the corresponding first support 30a1 and is disposed at each end of the battery receptacle 3s in the longitudinal direction. Each of the protrusions 30i comprises wall portions 30j, 30k, 30m, and 30n. The wall portion 30j is continuous to the wall portions 3n2 (3n). The wall portion 30k is interspaced with the wall portion 30j and is laid along the wall portion 30j. The wall portion 30m extends between the wall portion 30j and the wall portion 30k, and is continuous to the wall portion 3m. The wall portion 30n extends between the wall portion 30j and the wall portion 30k at the tip of the wall portion 30m. In a space surrounded by the wall portions 30j, 30k, 30m, and 30n of the protrusion 30i, a recessed portion 31a (space, component housing, housing) that opens to the inside of the housing 3B (on the side of the end 3e and the wall portion 3k) is formed by the wall portions 30j, 30k, 30m, and 30n. Each of the wall portions 30n is continuous to the corresponding wall portion 30m, is curved in an arc-like shape to the outside of the housing 3B in a manner convexed toward the side of the wall portion 3k and the front surface 3a (see FIGS. 9 and 11), and is formed as a part of the end 3c and the side surface 3p.

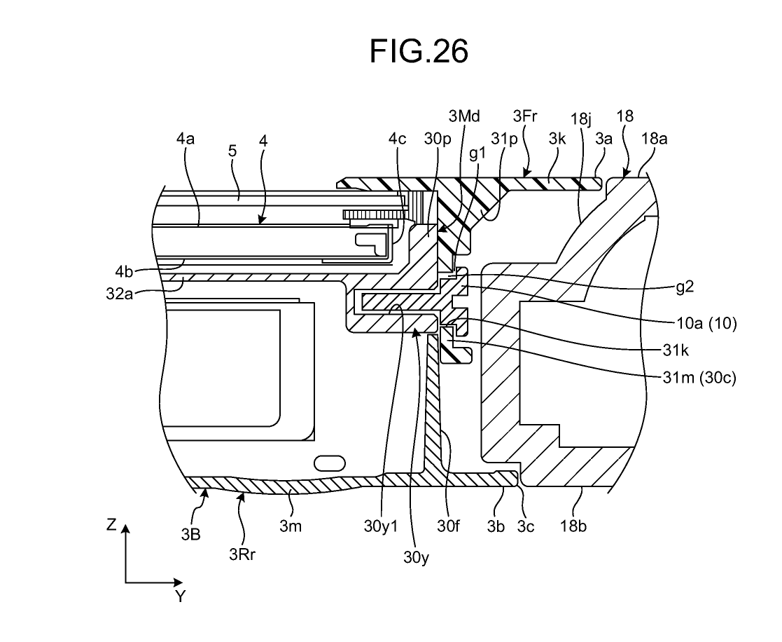

Furthermore, in the embodiment, as an example, as illustrated in FIG. 19, the third member 3Md (the third housing member) is formed in a rectangular shape (in the embodiment, an oblong shape, as an example) viewed from the front and viewed from the rear. Furthermore, the third member 3Md as a whole is formed in a plate-like form. Specifically, the third member 3Md comprises wall portions 32a, 30p, 30r, and 30s. The wall portion 32a is formed in a rectangular and plate-like shape, and supports a rear surface 4b of the display device 4 (see FIG. 26). The wall portion 32a is an example of a first wall portion. The wall portions 30p, 30r, and 30s are kept standing from the wall portion 32a on the perimeter of the wall portion 32a. The wall portion 30p is located at (laid along) the end 3c, and is structured as a part of the battery receptacle 3s and the battery support (second support 30a2), and faces the battery 18. The wall portion 30p is an example of a side wall. The wall portion 30r is located at (laid along) the end 3c and located on the side closer to the inside of the housing 3B than the wall portion 30p, faces a side surface 4c (covers the side surface 4c), and supports the side surface 4c of the display device 4 (see FIG. 26). The wall portions 30s are located at (laid along) the end 3d, 3e, and 3f, respectively, and are arranged on the side closer to the inside of the housing 3B than the wall portions 3n of the first member 3Fr or of the second member 3Rr, faces the side surface 4c (covers the side surface 4c), and supports the side surface 4c of the display device 4. Between the respective wall portions 3n and wall portions 30s, a recessed portion (space, component housing, housing) housing therein components such as a harness, a board, a connector, and the like is formed. The wall portions 30s are examples of an end. Furthermore, the wall portions 30r and 30s are examples of a second wall portion. The wall portion 30p is an example of a first end, and the wall portions 30s are examples of a second end.

The third member 3Md also comprises protrusions 30t each of which forms a part of the first support 30a1 located at each end of the battery receptacle 3s in the longitudinal direction. Each of the protrusions 30t comprises wall portions 30u, 30v, and 30w. The wall portion 30u is paralleled with (in parallel with) the wall portion 32a. The wall portion 30v extends from the wall portion 30p in a direction crossing (in the embodiment, a direction in perpendicular to, as an example) the wall portion 30p. The wall portion 30v also extends in a direction crossing (in the embodiment, a direction in perpendicular to, as an example) the wall portion 32a. The wall portion 30w extends between the tip of the wall portion 30u and the tip of the wall portion 30v. A recessed portion 31b (space, component housing, housing) opening to the inside of the housing 3B (on the side of the end 3e and on the side of the wall portion 3m) is formed by the wall portions 30u, 30v, and 30w. The recessed portions 31a formed in the second member 3Rr and the recessed portions 31b formed in the third member 3Md are laid on top of each other along the thickness direction of the housing 3B, to form component housings that are disposed at respective ends of the battery 18 in the longitudinal direction, and that open to the side of the end 3e of the housing 3B.

Furthermore, the coupling portions 30x, 30y, and 30z that are coupled to other housing members (first member 3Fr or second member 3Rr) are provided on the third member 3Md. The coupling portions 30x are provided on the wall portion 32a and are coupled to another housing member (in the second embodiment, the second member 3Rr as an example) through the coupling members such as the screws 10. The coupling portions 30x correspond to the coupling portions 30g (see FIG. 18) and are provided as openings (in the second embodiment, through-holes as an example) through which the coupling members (second coupling members) such as the screws 10 are inserted. Furthermore, the coupling portions 30y are provided on the wall portion 30p and are coupled to another housing member (in the second embodiment, the first member 3Fr as an example) through the coupling members such as the screws 10. The coupling portions 30y correspond to the coupling portions 30c and comprise coupling portions (in the second embodiment, internal threaded holes as an example) to which the coupling members such as the screws 10 are coupled. In addition, the coupling portions 30z are provided on the wall portion 30p and are engaged and coupled with/to the coupling portions 30d (engagement portions, see FIG. 17) of another housing member (in the second member, the first member 3Fr as an example).

In the embodiment, in the arrangement in which the battery 18 is received in (mounted on) the battery receptacle 3s, the third member 3Md is not exposed from the housing 3B. Therefore, in the embodiment, as an example, a process for improving the appearance, such as painting, does not have to be applied to the third member 3Md. In the embodiment, as an example, the second member 3Rr and the third member 3Md are made of metallic materials, and the first member 3Fr is made of a synthetic resin material. In other words, in the embodiment, as an example, the stiffness of the housing 3B is provided mainly by the second member 3Rr and the third member 3Md. Therefore, the stiffness of the first member 3Fr can be reduced compared with an arrangement not having the third member 3Md. In this manner, by distributing functions among a plurality of members, advantageous effects, such as a reduction in labors required in the production, may be achieved.

Furthermore, in the second embodiment, as illustrated in FIG. 19, a plurality of openings 31y (through holes as an example) are provided on the wall portion 32a of the third member 3Md, as an example. The third member 3Md, eventually, the electronic apparatus 1B can be configured to be more lightweight with the openings 31y, as an example. In addition, airflow performance in the housing 3B is easily improved with the openings 31y, as an example. As is also illustrated in FIG. 12, in the second embodiment, the openings 31y are not provided on a region As facing (opposed to) the substrate 6 and the fan 24, and the openings 31y are provided on a region Ao facing (opposed to) a region at the side opposite to the fan 24 with respect to the substrate 6 between the second member 3Rr and the third member 3Md, as an example. As for this point, according to the second embodiment, the air that has flown through the openings 31y on the wall portion 32a passes through (comes around, bypasses) the outer side of an end 6c (edge, see FIG. 14) of the substrate 6 at the side opposite to the fan 24 from the region at the side opposite to the fan 24 with respect to the substrate 6 so as to easily flow to a surface (second surface 6b) of the substrate 6 at the side opposite to the third member 3Md.

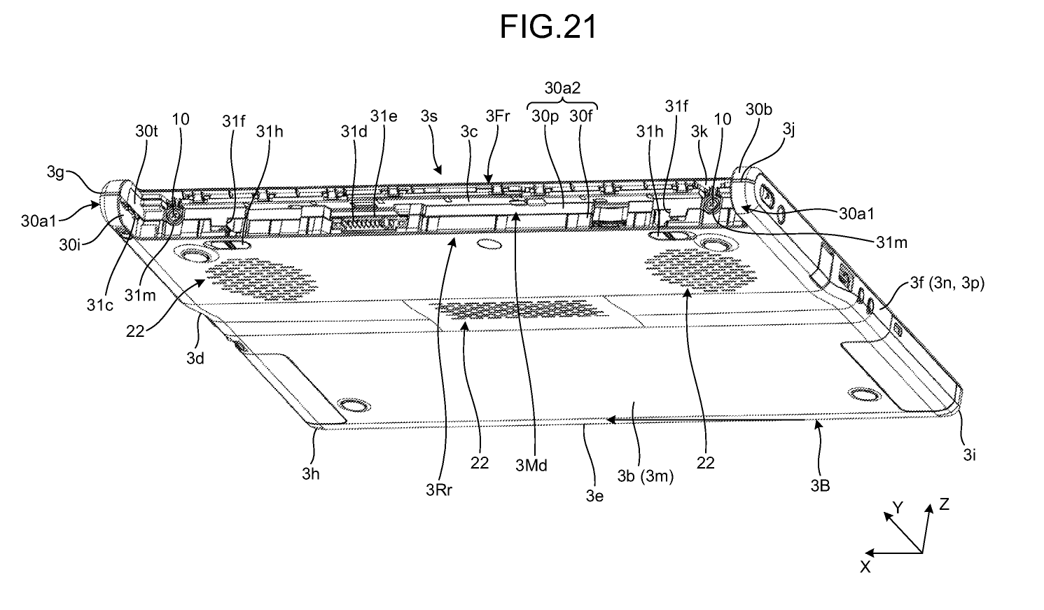

In the embodiment, as an example, as illustrated in FIGS. 20 and 21, the battery receptacle 3s is formed as a cutout portion (recessed portion, opening) formed on the end 3c of the housing 3B. When the battery 18 is received by (mounted on) the battery receptacle 3s, as illustrated in FIGS. 8, 9, and 11, for example, a surface 18a of the battery 18 and the front surface 3a of the housing 3B become continuous, a surface 18b on the opposite side of the surface 18a of the battery 18 and the rear surface 3b of the housing 3B become continuous. The surface 18a and the surface 18b are connected via a surface 18c (curved surface) curving in an arc-like form protruding outwardly.

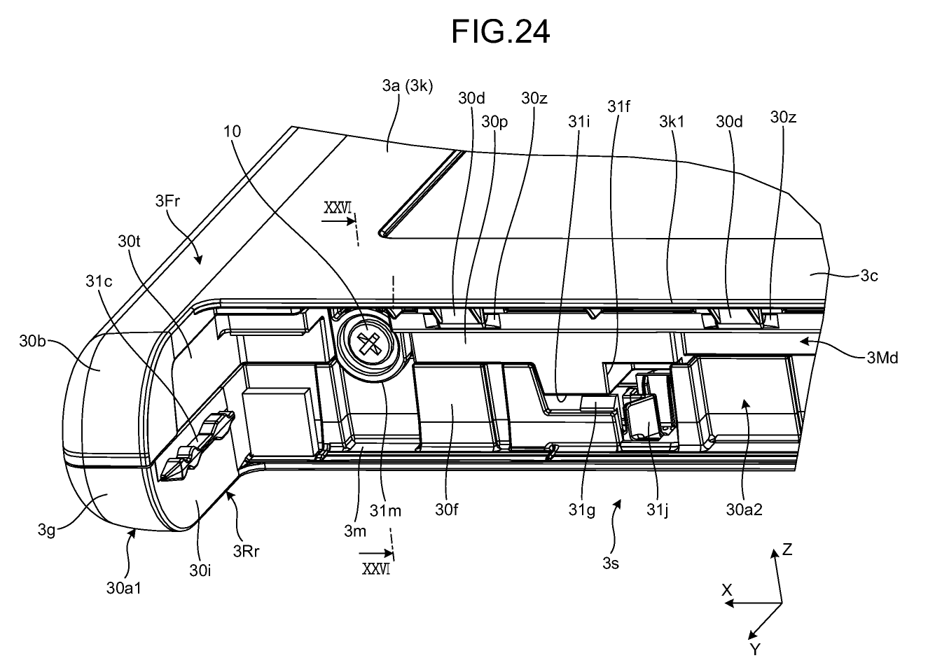

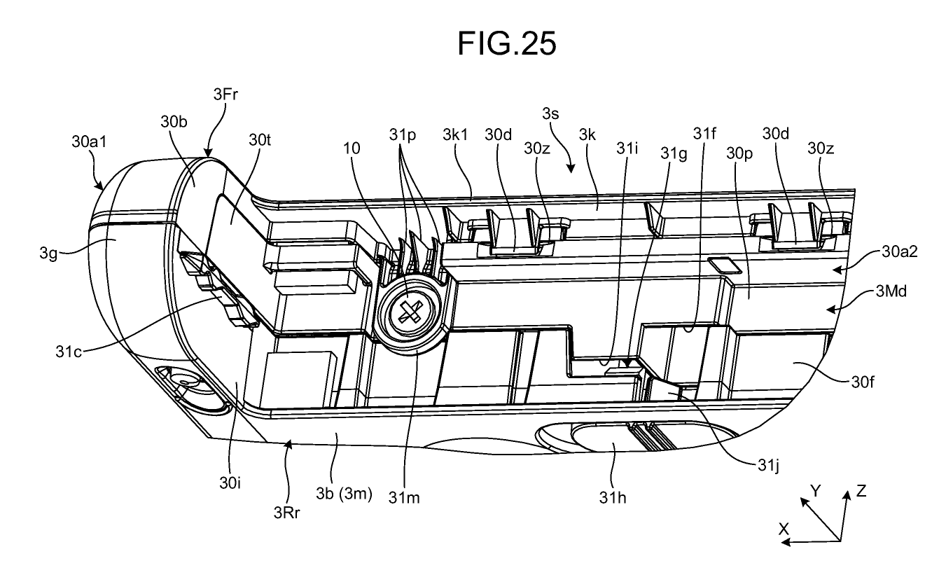

In the embodiment, as an example, the battery receptacle 3s is formed by a combination of the three housing members (the first member 3Fr, the second member 3Rr, and the third member 3Md). The battery 18 is mainly supported by the second member 3Rr and the third member 3Md. A part of the battery 18 (in the embodiment, a part closer to the housing 3B, a part along the end 3c of the housing 3B, as an example) is covered by the first member 3Fr, the second member 3Rr, and the third member 3Md. In the embodiment, as an example, both ends 18d of the battery 18 in the longitudinal direction are supported by the respective first supports 30a1. One end 18e of the battery 18 along the short side direction (an end laid along the end 3c of the housing 3B) is supported by the second support 30a2. Each of the first supports 30a1 comprises the protrusion 30i disposed on the second member 3Rr and the protrusion 30t disposed on the third member 3Md. The second support 30a2 comprises the wall portion 30f of the second member 3Rr and the wall portion 30p of the third member 3Md. The first support 30a1 and the second support 30a2 are examples of the battery support. In the embodiment, as an example, as illustrated in FIGS. 24 and 25, a part of the wall portion 30f of the second member 3Rr and a part the wall portion 30p of the third member 3Md both of which face the battery receptacle 3s are arranged side by side along the thickness direction of the housing 3B.

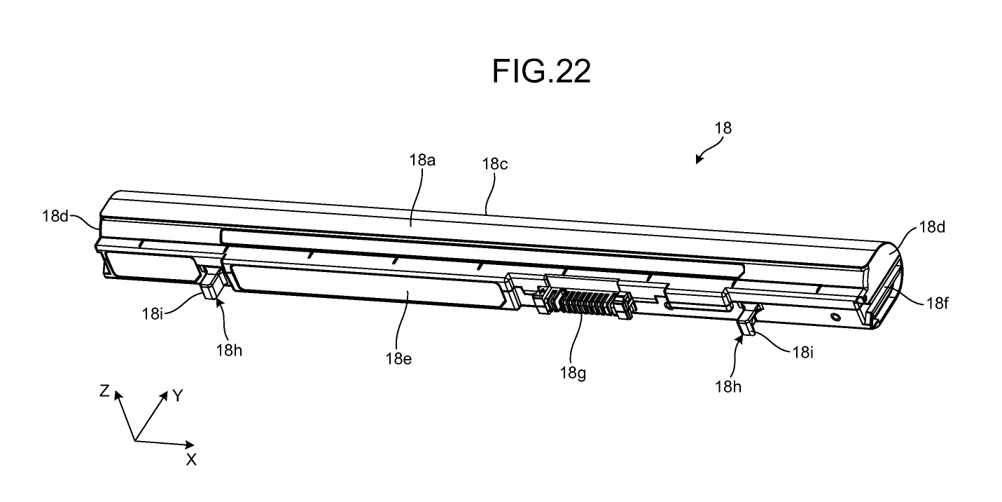

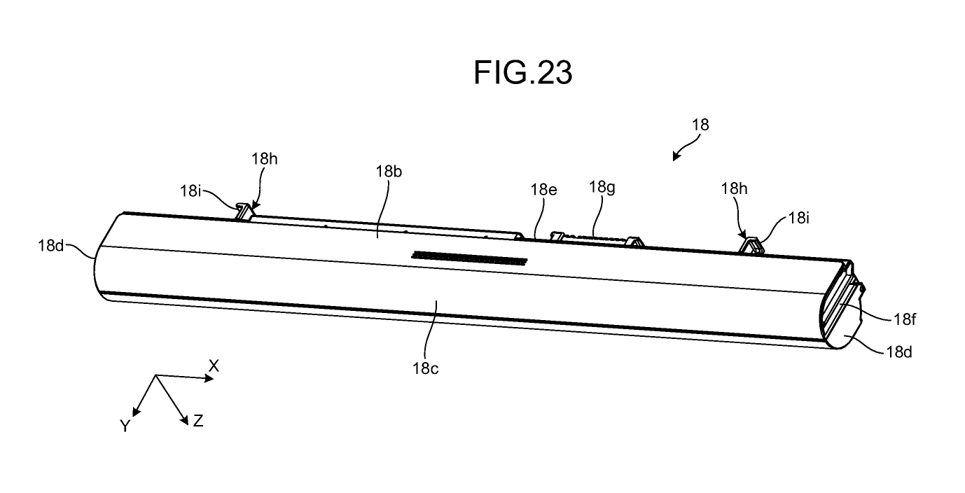

In the embodiment, as an example, as illustrated in FIGS. 22 and 23, each of the ends 18d of the battery 18 in the longitudinal direction comprises an engaged portion 18f that is engaged with the first support 30a1. Each of the engaged portions 18f is formed as a groove (recessed portion, opening) formed along an in-and-out direction of the battery 18 (mounting direction, attaching and removing direction, in the embodiment, as an example, the direction along the front surface 3a and the ends 3d and 3f, the Y direction), as an example. Correspondingly, each of the first supports 30a1 comprises an engaged portion 31c that is engaged with the corresponding engaged portion 18f, as illustrated in FIGS. 20 and 21. Each of the engaged portions 31c is formed as a protrusion (projection, wall) that is disposed on at least one of the second member 3Rr and the third member 3Md (in the embodiment, the second member 3Rr, as an example) and is inserted into the engaged portion 18f that is a groove. When a user and the like holding the battery 18 moves the battery 18 closer to the battery receptacle 3s and inserts the battery 18 into the battery receptacle 3s, the battery 18 is moved to a predetermined position (mounted position, coupled position) as the engaged portions 18f are guided by the respective engaged portions 31c. In other words, the engaged portions 31c and the engaged portions 18f are examples of a support and a guide portion (guiding portion).

On the end 18e of the battery 18 in the short side direction, a connector 18g and engaged portions 18h that are to be engaged with the second support 30a2 are disposed. The connector 18g protrudes from the end 18e of the battery 18. Correspondingly, a connector 31d that is mechanically and electrically connected to the connector 18g is disposed on the second support 30a2, as illustrated in FIGS. 20 and 21. The connector 31d is electrically connected to the board 6, and is exposed through an opening 31e disposed on the second support 30a2. The engaged portions 18h are structured as protrusions disposed at a plurality of points (in the embodiment, two, as an example) that are separated from each other along the longitudinal direction of the battery 18. A claw portion 18i (engaged portion, hook portion, hook) is formed on the tip of each of the engaged portions 18h. Correspondingly, openings 31f (recessed portions) into which the respective engaged portions 18h are inserted are disposed on the second support 30a2. Each of the opening 31f is formed as a gap (cutout) formed between the wall portion 30f of the second member 3Rr and the wall portion 30p of the third member 3Md in a boundary area between the wall portion 30f of the second member 3Rr and the wall portion 30p of the third member 3Md, as illustrated in FIGS. 24 and 25. A gap can be manufactured more easily compared with a through-hole. Therefore, according to the embodiment, as an example, a labor for manufacturing the openings 31f can be reduced easily. Furthermore, in the embodiment, as an example, an engaged portion 31g (movable portion) supported on the housing 3B (at least one of the second member 3Rr and the third member 3Md; in the embodiment, both, as an example) in a slidable (movable, displaceable) manner is disposed in the opening 31f. A claw portion 31j (engaged portions, hook portion, hook) that is engaged with the corresponding claw portion 18i is disposed on the tip of each of the engaged portions 31g. The engaged portions 31g are connected to a manipulator 31h (component, slider) disposed in a manner exposed from the housing 3B, and operate (interoperate) with the manipulator 31h. The engaged portions 31g are moved in a manner guided by respective guide portions 31i of the housing 3B. In the embodiment, as an example, each of the guide portions 31i is formed as a gap (cutout, silt) formed between the ends (end edges, edges, sides) of the wall portion 30f of the second member 3Rr and the wall portion 30p of the third member 3Md in the boundary area of the wall portion 30f of the second member 3Rr and the wall portion 30p of the third member 3Md. A gap can be manufactured more easily compared with a through-hole. Therefore, according to the embodiment, as an example, a labor for manufacturing the engaged portions 31g can be reduced easily. In such a structure, as the battery 18 is guided into the battery receptacle 3s, the engaged portions 18h are inserted into the respective openings 31f. When a user moves the manipulator 31h from a free side (releasing side) to a locking side (fixing side) using a finger or a hand while the battery 18 is positioned at a predetermined position (mounted position, coupled position) with respect to the housing 3B, the claw portion 31j of each of the engaged portions 31g is engaged with the claw portion 18i disposed on each of the engaged portions 18h, and the battery 18 is locked (fixed) at a predetermined position (mounted position, incoming position).

Furthermore, in the embodiment, as an example, as illustrated in FIGS. 24 and 25, the wall portion 30f of the second member 3Rr and the wall portion 30p of the third member 3Md covered by the battery 18 have a recessed form or projected form (recessed portion and projected portion) recessed or projected in the normal direction (Y direction) of the wall portion 30f and the wall portion 30p. In this manner, the stiffness of the end 3c of the housing 3B covered by the battery 18 can be improved easily.

Furthermore, in the embodiment, as an example, as illustrated in FIGS. 25 and 26, the coupled portions 30c and 30d disposed on the first member 3Fr are coupled to at least one of the second member 3Rr and the third member 3Md (in the embodiment, the third member 3Md, as an example) from the outside of the housing 3B. Specifically, each of the coupled portions 30c comprises a protrusion 31m having an opening 31k through which a coupler such as the screw 10 is passed, as illustrated in FIG. 26. The protrusion 31m protrudes from the wall portion 3k toward the wall portion 3m in the thickness direction of the housing 3B. The protrusion 31m extends along the surface (external surface) of the wall portion 30p of the third member 3Md and of the wall portion 30f of the second member 3Rr. In other words, the protrusions 31m cover the wall portions 30p and 30f from the outside of the housing 3B. Each of the coupled portions 30d (engaged portions) is engaged with the corresponding coupled portion 30z (engaged portion) disposed on an end of the wall portion 30p of the third member 3Md on the side closer to the wall portion 3k from the outside of the housing 3B, as illustrated in FIG. 25. In an arrangement in which the coupled portions 30c and 30d of the first member 3Fr cover at least one of the second member 3Rr and the third member 3Md from the outside of the housing 3B when the battery 18 is removed, as an example, the coupling achieved by the coupled portions 30c and 30d can be released easily.

Furthermore, in the embodiment, as an example, as illustrated in FIG. 26, the screw 10 coupled to the coupled portion 30c disposed on the first member 3Fr and to the coupled portion 30y disposed on at least one of the second member 3Rr and the third member 3Md (in the embodiment, as an example the third member 3Md) is positioned on the opposite side of the display screen 4a with respect to the display device 4. Therefore, as an example, compared with an arrangement in which the screw 10 and the display device 4 come on top of each other in a direction along the display screen 4a (an arrangement in which the screw 10 is positioned along the normal direction of the side surface 4c with respect to the display device 4), the length by which the housing 3B extends out of the side surface 4c (edge) of the display screen 4a viewed from the front can be reduced further. Therefore, as an example, the size of the housing 3B with respect to the size of the display device 4 can be further reduced easily.

Furthermore, in the arrangement according to the embodiment, each of the protrusions 31m extends in a direction moving away from the wall portion 3k, and the point (tip, end) of each of the protrusions 31m and each of the coupled portions 30d are separated from each other. Therefore, as an example, when an operator, after releasing the coupling of the coupled portions 30c and the coupled portion 30y, applies a force to (the tip of) the protrusion 31m in direction which the protrusion 31m is removed from the wall portions 30p and 30f (the direction toward the right, the direction toward the upper right in FIG. 26) with a hand, a finger, or a tool (e.g., a slotted screwdriver), the moment arm to the coupled portion 30d is further extended. Therefore, the engagement between the coupled portion 30d and the coupled portion 30z can be released easily. Furthermore, by disposing the screw 10 behind the display device 4, the moment arm can be further better extended. Protrusions 31p (wall portions, ribs) extending in a direction crossing both of the protrusion 31m and the wall portion 3k are formed at the root (base end) of the protrusion 31m. Therefore, according to the embodiment, when the protrusion 31m is bent, the root can be better prevented from being deformed.

Furthermore, in the second embodiment, as illustrated in FIGS. 25 and 26, the wall portion 3k projects (protrudes) from the wall portion 30p in a direction of being separated from a center of the housing 3B, as an example. Therefore, after an operator releases coupling between the coupling portions 30c and the coupling portions 30y, when the operator makes a force act on the end 3k1 (edge, side) of the wall portion 3k in a direction (upward direction, upward left direction in FIG. 26) of being separated from the wall portion 3m with a hand, a finger, a tool, or the like, a moment arm for the coupling portions 30d is longer. Therefore, engagement between the coupling portions 30d and the coupling portions 30z is made to be easily released. Furthermore, the opening 18j is provided on the battery 18 so as to correspond to the projected portion of the wall portion 3k. Accordingly, the thickness of the housing 3B is not easy to be larger.

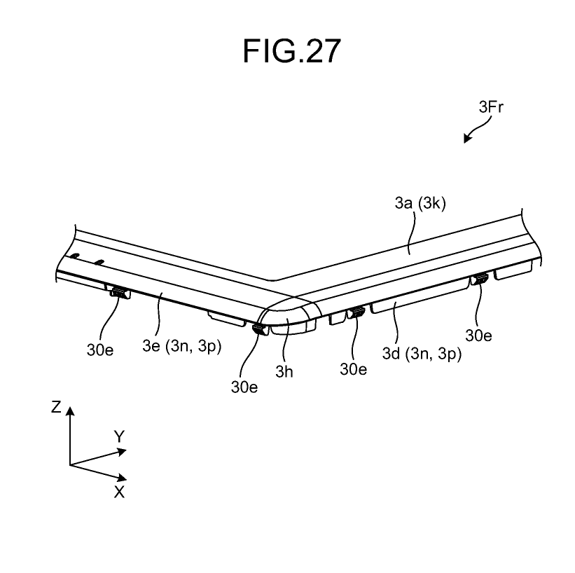

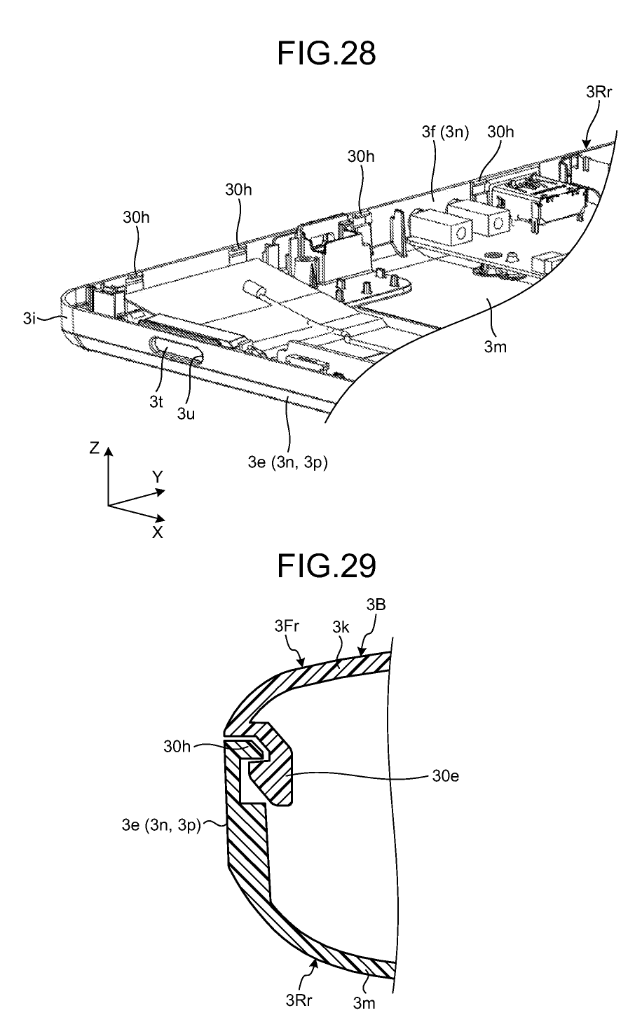

Furthermore, in the embodiment, as an example, as illustrated in FIGS. 27 to 29, the coupled portions 30e arranged on the first member 3Fr and the coupled portions 30h arranged on at least one of the second member 3Rr and the third member 3Md (in the embodiment, the second member 3Rr, as an example) are disposed nearer to the inside of the housing 3B than the wall portions 3n of the housing 3B on the ends 3d, 3e, and 3f, but not on the end 3c along the side of the battery receptacle 3s. In other words, the coupled portions 30e and 30h are covered by at least one of the first member 3Fr and the third member 3Md. Therefore, according to the embodiment, as an example, the coupled portions 30e and 30h can be prevented from being exposed. Therefore, for example, inconvenience caused by the coupled portions 30e and 30h being exposed from the housing 3B, such as the coupling is more easily released or disfigurement is caused, can be prevented.

Furthermore, in the embodiment, as an example, coupling between the first member 3Fr and at least one of the second member 3Rr and the third member 3Md is based on an engagement (hooking) between the coupled portions (30c, 30y), except that the coupling between the coupled portions 30c and the coupled portion 30y, which are covered by the battery 18, is via couplers such as the screws 10. Therefore, according to the embodiment, as an example, by providing a coupled portion that is more securely coupled via couplers to at least to the end 3c, the first member 3Fr and at least one of the second member 3Rr and the third member 3Md can be coupled more securely. At the same time, inconvenience caused by an increased number of locations coupled via couplers, such as the size or a weight increase, can be prevented.

The coupling (engagement) on the coupling portions 30e and 30h on the ends 3d, 3e, and 3f other than the end 3c at the side of the battery accommodation portion 3s between the first member 3Fr and at least one of the second member 3Rr and the third member 3Md may be performed as follows. That is, the first member 3Fr and at least one of the second member 3Rr and the third member 3Md may be coupled to each other by making them closer to each other in a direction along the display screen 4a or may be coupled to each other by making them closer to each other in a direction intersecting with the display screen 4a. With a configuration (so-called snap-fit system) in which they are coupled by making them closer to each other in the direction along the display screen 4a, attachment/detachment is performed more easily. On the other hand, with a configuration (so-called slide system) in which they are coupled by making them closer to each other in the direction intersecting with the display screen 4a, engagement portions of the coupling portions 30e and 30h can be configured to be larger in comparison with the configuration of the so-called snap-fit system so that coupling forces by the coupling portions 30e and 30h are easy to be larger.

Furthermore, in the second embodiment, as illustrated in FIGS. 12 and 30, the second member 3Rr and the third member 3Md are coupled to each other with the coupling members (second coupling members) such as the screws 10 and the coupling portions 30x and 30g (see FIGS. 18 and 19) with the coupling members are covered by the display device 4 or the first member 3Fr, as an example. Therefore, according to the second embodiment, the coupling portion 30x and 30g between the second member 3Rr and the third member 3Md as two housing members that mainly keep rigidity and strength can be suppressed from being exposed to the outside of the housing 3B, as an example. This makes it possible to suppress disadvantages due to exposure of the coupling portions 30x and 30g from occurring. As the disadvantages, coupling is easily released, and appearance is easily spoiled, for example.

Furthermore, in the second embodiment, a recess 31r (opening) that is recessed toward the second member 3Rr side is provided on the wall portion 32a of the third member 3Md, as an example. To be more specific, the recess 31r is provided between the opposing ends 3d and 3f so as to be in parallel with the ends 3c and 3e. A step-like (inclined surface-like) wall portion 31s is provided on a boundary portion of the recess 31r. Rigidity of the third member 3Md is easily improved by the wall portion 31s. Therefore, according to the second embodiment, with the recess 31r, a space (region) in which a substrate 4d of the display device 4 is accommodated is ensured and the rigidity of the third member 3Md is easily improved, as an example.

Furthermore, in the second embodiment, coupling of the coupling portions 30e and 30h on the end 3e as illustrated in FIG. 29 is totally the same as the coupling of the coupling portions 30e and 30h on the end 3c as illustrated in FIG. 3 in the above first embodiment. In addition, coupling of the coupling portions 30c and 30y on the end 3c as illustrated in FIG. 26 is totally the same as the coupling of the coupling portions 30c and 30y on the end 3e as illustrated in FIG. 4 in the above first embodiment. Accordingly, in the second embodiment, the same effects as those in the above first embodiment can be obtained.

First Variation

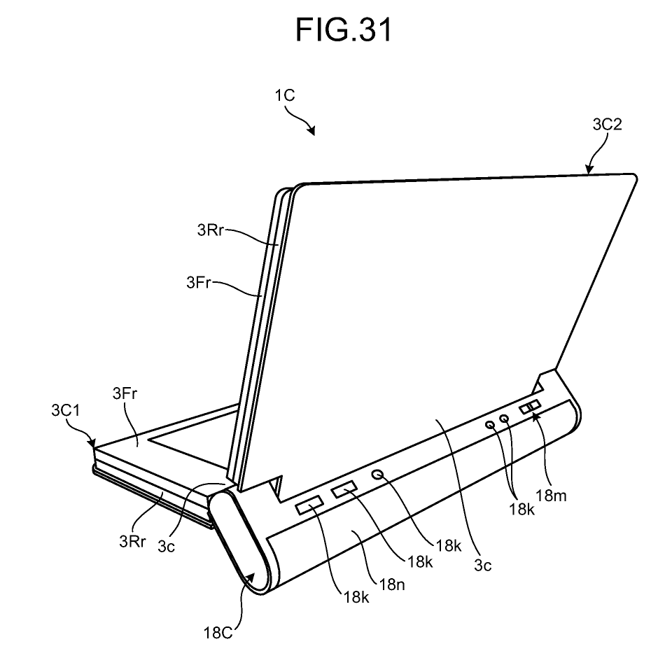

In an electronic apparatus 1C according to the first variation, as illustrated in FIG. 31, two housings 3C1 and 3C2 are connected to each other through a hinge unit 18C in a rotationally movable manner, as an example. In the first variation, the coupling portions 30c and 30y (not illustrated in FIG. 31) and screws 10 (not illustrated in FIG. 31) as coupling members that are the same as in the above embodiments and are provided on the ends 3c of the housings 3C1 and 3C2 can be covered not by a module such as a battery but by the hinge unit 18C as a functional part. With a configuration in the first variation, the same effects as those in the above embodiments can be also obtained. It is to be noted that a connector 18k, a switch 18m (operation module), a battery 18n, and the like can be provided on the hinge unit 18C.

Second Variation

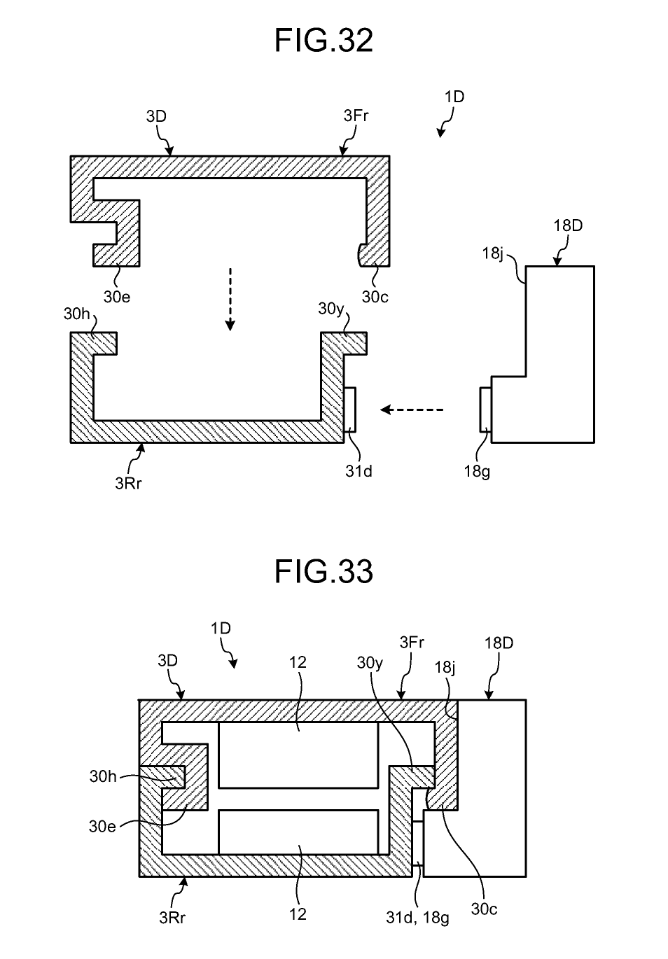

In an electronic apparatus 1D according to the second variation, as illustrated in FIGS. 32 and 33, a housing 3D comprises the first member 3Fr and the second member 3Rr. One ends (ends at the left side in FIGS. 32 and 33) of the first member 3Fr and the second member 3Rr are coupled to each other with coupling portions 30e and 30h (engagement portions, claw portions). The other ends (ends at the right side in FIGS. 32 and 33) are coupled to each other with the coupling portions 30c and 30y (engagement portions, claw portions). Furthermore, in the second variation, the coupling portion 30h is also located at an outer position of the housing with respect to the coupling portion 30e and the coupling portion 30y is also located at an inner position of the housing with respect to the coupling portion 30c. In addition, a battery 18D as a functional part (module) is attached to the housing 3D in a detachable manner so as to cover at least a part of the coupling portions 30c and 30y. A connector 18g of the battery 18D is coupled to and is electrically connected to a connector 31d provided at a position separated from the coupling portions 30c and 30y. The opening (recess) 18j is provided on the battery 18D. At least a part of the coupling portions 30c and 30y is accommodated in the opening 18j. At least the coupling portions 30c and 30y are coupled to each other by making them closer to each other in the thickness direction of the housing 3D (up-down direction in FIGS. 32 and 33) (so-called snap-fit system). With this configuration, the same effects as those in the above embodiments and the above variation can be also obtained. In addition, according to the second variation, when the opening 18j is provided on the battery 18D, the coupling portions 30c and 30y can be positioned by effectively using the opening 18j, as an example. Furthermore, according to the second variation, when a display device as an electronic part 12 is accommodated in the housing 3D, the display device can be provided so as to be closer to an end at the side of the coupling portions 30c and 30y, as an example. It is to be noted that although not illustrated in FIGS. 32 and 33, the first member 3Fr and the second member 3Rr can be coupled to each other on the coupling portions 30c and 30y or other portions with a coupling member such as a screw.

Third Variation

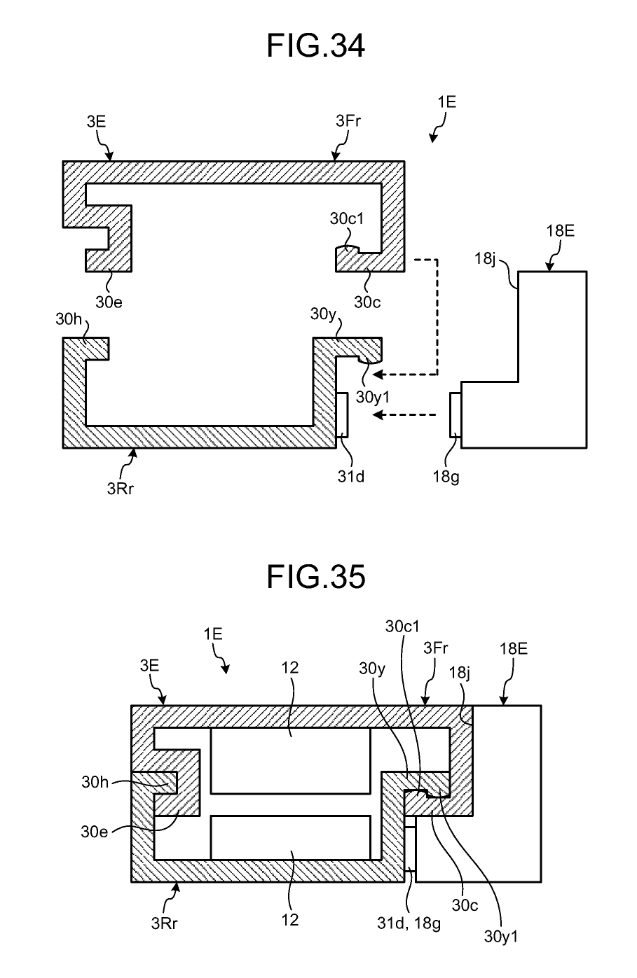

In an electronic apparatus 1E according to the third variation, as illustrated in FIGS. 34 and 35, a housing 3E comprises the first member 3Fr and the second member 3Rr. One ends (ends at the left side in FIGS. 34 and 35) of the first member 3Fr and the second member 3Rr are coupled to each other with coupling portions 30e and 30h (engagement portions, claw portions). The other ends (ends at the right side in FIGS. 34 and 35) thereof are coupled to each other with the coupling portions 30c and 30y (engagement portions, claw portions). Furthermore, in the third variation, the coupling portion 30h is also located at an outer position of the housing with respect to the coupling portion 30e and the coupling portion 30y is also located at an inner position of the housing with respect to the coupling portion 30c. In addition, a battery 18E as a functional part (module) is attached to the housing 3E in a detachable manner so as to cover at least apart of the coupling portions 30c and 30y. The connector 18g of the battery 18E is coupled to and is electrically connected to the connector 31d provided at a position separated from the coupling portions 30c and 30y. The opening (recess) 18j is provided on the battery 18E. At least a part of the coupling portions 30c and 30y is accommodated in the opening 18j. The coupling portions 30e and 30h and the coupling portions 30c and 30y are coupled to each other by making them closer to each other in the direction intersecting with the thickness direction of the housing 3E (orthogonal direction, right-left direction in FIGS. 34 and 35) (so-called slide system). Furthermore, a snap-fit mechanism (disengagement prevention mechanism, disengagement prevention portion, coupling portion, engagement portion) with protrusions 30c1 and 30y1 (claws, engagement portions) is configured in the direction (orthogonal direction, slide direction) intersecting with the thickness direction on the coupling portions 30c and 30y at one of two ends. With this configuration, the same effects as those in the above embodiments and the above variations can be also obtained, as an example. In addition, in the third variation, when the opening 18j is provided on the battery 18E, the coupling portions 30c and 30y can be also positioned by effectively using the opening 18j, as an example. Furthermore, in the third variation, when a display device as the electronic part 12 is accommodated in the housing 3E, the display device can be also provided so as to be closer to an end at the side of the coupling portions 30c and 30y. It is to be noted that although not illustrated in FIGS. 34 and 35, the first member 3Fr and the second member 3Rr can be coupled to each other on the coupling portions 30c and 30y or other portions with a coupling member such as a screw.

Fourth Variation

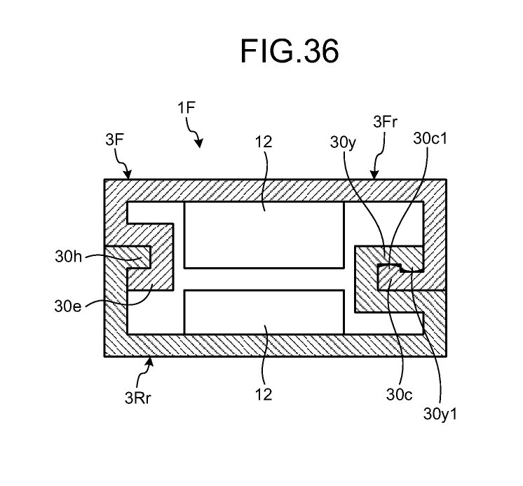

In an electronic apparatus 1F according to the fourth variation, as illustrated in FIG. 36, a housing 3F comprises the first member 3Fr and the second member 3Rr. One ends (ends at the left side in FIG. 36) of the first member 3Fr and the second member 3Rr are coupled to each other with coupling portions 30e and 30h (engagement portions, claw portions). The other ends (ends at the right side in FIG. 36) are coupled to each other with the coupling portions 30c and 30y (engagement portions, claw portions). Furthermore, in the fourth variation, the coupling portion 30h is also located at an outer position of the housing with respect to the coupling portion 30e and the coupling portion 30y is also located at an inner position of the housing with respect to the coupling portion 30c. However, in the fourth variation, the coupling portions 30c and 30y are not covered by a functional part (module) such as a battery. The coupling portions 30e and 30h and the coupling portions 30c and 30y are coupled to each other by making them closer to each other in the direction (orthogonal direction) intersecting with the thickness direction of the housing 3F (so-called slide system). Furthermore, a snap-fit mechanism (disengagement prevention mechanism, disengagement prevention portion, coupling portion, engagement portion) with protrusions 30c1 and 30y1 (claws, engagement portions) is configured in the direction (orthogonal direction, slide direction) intersecting with the thickness direction on the coupling portions 30c and 30y at one of two ends. With this configuration, the same effects as those in the above embodiments and the above variations can be also obtained, as an example. It is to be noted that although not illustrated in FIG. 36, the first member 3Fr and the second member 3Rr can be coupled to each other on the coupling portions 30c and 30y or other portions with the coupling member such as the screw.

As described above, the embodiments of the invention have been described. However, the above embodiments are merely examples. The invention is not limited to the above embodiments and various variations can be made. For example, a clip or the like other than the screw can be used as a coupling portion. Furthermore, a part (for example, HDD unit, optical disk drive (ODD) unit) other than a battery can be used as a module or a functional part. In addition, technical characteristics in the above embodiments can be combined as appropriate. Furthermore, the specifications (configuration, type, direction, shape, size, length, width, thickness, height, number, arrangement, position, material, and the like) of each constituent component can be changed as appropriate.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display comprising a screen and an edge at an area other than the screen;
a first housing portion covering at least a part of the edge of the display;
a second housing portion at a side opposite the display;
a third housing portion at a side opposite the screen, between the second housing portion and the screen;
a first coupling portion at one end of the first housing portion;
a second coupling portion at one end of at least one of the second housing portion and the third housing portion, outside the first coupling portion, and coupled to the first coupling portion;
a third coupling portion at the other end of the first housing portion;
a fourth coupling portion at the other end, with respect to the second coupling portion, of at least one of the second housing portion and the third housing portion, inside the third coupling portion, and coupled to the third coupling portion;
a coupling member configured to couple the third coupling portion and the fourth coupling portion, at least a part of the coupling member outside the third coupling portion; and
a module attached to at least one of the second housing portion and the third housing portion, the module covering the coupling member from outside at least one of the second housing portion and the third housing portion.

2. The television receiver of claim 1, wherein the third coupling portion and the fourth coupling portion are coupled to each other by making the third coupling portion and the fourth coupling portion closer to each other in a direction intersecting with the screen.

3. The television receiver of claim 1, wherein the third coupling portion and the fourth coupling portion are coupled to each other by making the third coupling portion and the fourth coupling portion closer to each other in a direction along the screen.

4. The television receiver of claim 1, wherein at least a part of the third coupling portion is in a recess in the module.

5. The television receiver of claim 1, wherein the coupling member is at the side opposite the screen of the display.

6. The television receiver of claim 5, wherein the coupling member is extends in a direction along the screen.

7. The television receiver of claim 5, wherein the third coupling portion and the fourth coupling portion are displacably connected to each other within a first range.

8. The television receiver of claim 1, further comprising:
a second coupling member configured to couple the second housing portion and the third housing portion, wherein
at least a part of the second coupling member is covered by the display.

9. The television receiver of claim 1, wherein the first housing portion comprises a synthetic resin material, and the second housing portion and the third housing portion comprise a metal material.

10. An electronic apparatus comprising:
a first housing portion configured to cover a part of an electronic component;
a second housing portion configured to cover another part of the electronic component that is different from the part covered by the first housing portion;
a first coupling portion at one end of the first housing portion;
a second coupling portion at one end of the second housing portion, outside the first coupling portion, and coupled to the first coupling portion;
a third coupling portion at the other end of the first housing portion;
a fourth coupling portion at the other end, with respect to the second coupling portion, of the second housing portion, inside the third coupling portion, and coupled to the third coupling portion; and
a function component attached to the second housing portion, the function component covering the third coupling portion.
